(19) United States
(12) Patent Application Publication
(10) Pub. No.: US 2005/0218466 A1
(43) Pub. Date: Oct. 6, 2005

(54) Thin-film lamination, and actuator device, filter device, ferroelectric memory, and optical deflection device employing the thin -film lamination

(75) Inventors: Masao Kondo, Kawasaki (JP); Kazuaki Kurihara, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 10/972,953

(22) Filed: Oct. 26, 2004

(30) Foreign Application Priority Data
Mar. 31, 2004 (JP) 2004-105975

(51) Int. Cl. H01L 21/00; H01L 29/84

(52) U.S. Cl. 257/415; 438/50; 257/416

(57) ABSTRACT

A thin-film lamination includes: a monocrystal substrate; an intermediate layer having zirconia as a main constituent produced in an epitaxial growth manner on the monocrystal substrate; a C-rare earth structure film comprising oxide having a C-rare earth crystal structure produced on the intermediate layer in an epitaxial growth manner; and a simple perovskite structure film comprising a metal oxide of a crystal structure having simple perovskite lattices produced on the C-rare earth structure film in an epitaxial growth manner.

### CROSS-REFERENCE TO RELATED APPLICATIONS

This application is based upon and claims the benefit of priority from the prior Japanese Patent Application No. 2004-105975, filed in Mar. 31, 2004, the entire contents of which are incorporated herein by reference.

### BACKGROUND OF THE INVENTION

1. Field of the Invention

The present invention relates to a thin-film lamination in which a thin film having piezoelectric property, electrostriction property, ferroelectric property or electro-optical property may be produced in an epitaxial growth manner, an actuator device a filter device, a ferroelectric memory and an optical deflection device employing the laminations.

2. Description of the Related Art

Research has been actively proceeded with for a ferroelectric memory (FeRAM) employing ferroelectric substance having spontaneous polarization is used in a capacitor part in a non-volatile memory mainly applied for a next generation, and study has been made to apply it to a non-contact IC card or such. Further, other application to an actuator device such as a piezoelectric pump driven by means of electrostriction property, a gyro-sensor device, a filter device for communication technical field or such, produced as a result of a ferroelectric film produced on a silicon substrate being fabricated with the use of semiconductor fine fabricating technology, has been also studied. Further, other application is also considerable, in which, with the use of change in a refractive index (electro-optic effect) which occurs when a voltage is applied to a ferroelectric film, an optical switch or such used for changing a path of light propagated in the ferroelectric substance may be created. Since ferroelectric substance has anisotropy in a polarization direction, it is preferable to cause an orientation of a crystal direction indicating a maximum polarization amount to lie along a substrate perpendicular direction, for the purpose of creating a high performance electronic device.

In order to obtain an oxide epitaxial film having high transmittance and low light loss, oxide monocrystal substrate such as magnesium oxide (MgO), strontium titanate (SrTiO₃), or such were employed. However, since a Czochralski method cannot be applied for the oxide monocrystal substrate, it is difficult to achieve a large size thereof, and, merely it is possible to achieve a size of at most on the order of 2 inches. Accordingly, it is advantageous when the substrate can be replaced by a silicon substrate, for example, since the silicon substrate can be produced to have a size on the order of 300 mm, whereby it is possible to produce many electronic devices through a single process, and thus, it is possible to effectively reduce the costs.

Japanese Laid-open Patent Application No. 09-110592 discloses that a structure is obtained in which, with the use of a zirconia film produced on a silicon substrate as a base layer, oxide having a simple perovskite structure is produced in an epitaxial growth manner in a (001) plane direction.

### SUMMARY OF THE INVENTION

According to one aspect of the present invention, a thin-film lamination is provided which includes: a monocrystal substrate; an intermediate layer having zirconia as a main constituent produced in an epitaxial growth manner on the monocrystal substrate; a C-rare earth structure film made of oxide having a C-rare earth crystal structure produced on the intermediate layer in an epitaxial growth manner; and a simple perovskite structure film made of metal oxide of a crystal structure having simple perovskite lattices produced on the C-rare earth structure film in an epitaxial growth manner.

As a result of a layer made of one of various materials being produced between a monocrystal substrate and a simple perovskite structure film made of metal oxide of a crystal structure having simple perovskite lattices, the inventors of the present invention found out a method of disposing in a (001) plane direction a layer made of one of various materials between the monocrystal semiconductor substrate and the simple perovskite structure film by producing an oxide film having a crystal structure of a C-rare earth structure on a zirconia film.

According to the present invention, since the perovskite structure film is produced on the monocrystal substrate via the intermediate layer in an epitaxial growth manner with a crystal growth plane of (001) plane in the thin-film lamination, it becomes possible to further produce, on this thin-film lamination, a metal oxide of a crystal structure having perovskite lattices, for example, a ferroelectric film in an epitaxial growth manner, and also, to cause a crystal growth direction, i.e., a lamination direction thereof to orient also in the (001) direction. Accordingly, it is possible that a polarization direction and the lamination direction is made to be coincident with one another in the ferroelectric film, and thereby, it is possible to improve piezoelectric property, electrostriction property, a residual polarization amount or electro-optical effect of an actuator device driven as a result of a voltage being applied in the lamination direction, a filter device, a ferroelectric memory including a capacitor device or an optical deflection device.

According to another aspect of the present invention, an actuator device is provided which includes: a monocrystal substrate; an intermediate layer having zirconia as a main constituent produced in an epitaxial growth manner on the monocrystal substrate; a C-rare earth structure film made of oxide having a C-rare earth crystal structure produced on the intermediate layer in an epitaxial growth manner; and a simple perovskite structure film made of metal oxide of a crystal structure having simple perovskite lattices produced on the C-rare earth structure film in an epitaxial growth manner; a lower electrode layer including a platinum group element or an alloy containing a platinum group element produced in an epitaxial growth manner on the simple perovskite structure film; an oxide film made of metal oxide of a crystal structure having simple perovskite lattices produced on the lower electrode film in an epitaxial growth manner; and an upper electrode film produced on the oxide film, and wherein: the oxide film has piezoelectric property or electrostriction property.

In this configuration, when a voltage is applied between the lower electrode and the upper electrode, a direction of an electric field thus produced coincides with a direction of (001) plane of the oxide film which exhibits piezoelectric property or electrostriction property, and as a result, it is possible to achieve the actuator device having superior piezoelectric property and electrostriction property, and having a large displacement amount.

According to another aspect of the present invention, a filter device is provided which includes: a monocrystal substrate; an intermediate layer having zirconia as a main constituent produced in an epitaxial growth manner on the monocrystal substrate; a C-rare earth structure film made of oxide having a C-rare earth crystal structure produced on the intermediate layer in an epitaxial growth manner; a simple perovskite structure film made of metal oxide of a crystal structure having simple perovskite lattices produced on the C-rare earth structure film in an epitaxial growth manner; an oxide film made of metal oxide of a crystal structure having simple perovskite lattices produced on the simple perovskite structure film in an epitaxial growth manner; and an input electrode and an output electrode produced on the oxide film, wherein: said oxide film has piezoelectric property.

In this configuration, since crystallinity of the oxide film has superior and thus piezoelectric property is obtained therefrom, it is possible to improve an efficiency of transformation from an electric signal to an elastic wave or from an elastic wave to an electric signal, and to provide the filter device having a reduced energy loss.

According to another aspect of the present invention, a ferroelectric memory is provided which includes: a monocrystal substrate in which two impurity diffusion regions connected with a source and a drain, respectively, are produced thereon; a thin-film lamination produced on the monocrystal substrate; and a gate electrode on the thin-film lamination, wherein: said thin-film lamination includes: an intermediate layer having zirconia as a main constituent produced in an epitaxial growth manner on the monocrystal substrate; a C-rare earth structure film made of oxide having a C-rare earth crystal structure produced on the intermediate layer in an epitaxial growth manner; a simple perovskite structure film made of metal oxide of a crystal structure having simple perovskite lattices produced on the C-rare earth structure film in an epitaxial growth manner; and an oxide film made of metal oxide of a crystal structure having simple perovskite lattices produced on the simple perovskite structure film in an epitaxial growth manner, and wherein: the oxide film has ferroelectric property.

In this configuration, since a direction of polarization in the oxide film and a direction between the gate electrode and the monocrystal substrate become coincident with one another, it is possible to increase a residual polarization amount. Accordingly, it is possible to achieve the ferroelectric memory having superior data holding capability or fatigue characteristics, and thus, having increased long-age reliability.

According to another aspect of the present invention, an optical deflection device is provided which includes: a monocrystal substrate; an intermediate layer having zirconia as a main constituent produced in an epitaxial growth manner on the monocrystal substrate; a C-rare earth structure film made of oxide having a C-rare earth crystal structure produced on the intermediate layer in an epitaxial growth manner; and a simple perovskite structure film made of metal oxide of a crystal structure having simple perovskite lattices produced on the C-rare earth structure film in an epitaxial growth manner; a lower electrode layer including a platinum group element or an alloy containing a platinum group element produced in an epitaxial growth manner on the simple perovskite structure film; a first oxide film produced on the lower electrode layer in an epitaxial growth manner; a second oxide film made produced on the first oxide film in an epitaxial growth manner; and an electrode produced on the second oxide film, and wherein: each of the first oxide film and the second oxide film made of metal oxide having simple perovskite lattices and also having electro-optical effect; and the second oxide film has a refractive index higher than that of the first oxide film.

In this configuration, since a polarization direction in a clad layer and a core layer coincides with a direction between the lower electrode layer and the upper electrode layer, it is possible to achieve the optical deflection device superior in electro-optical effect, having an increased deflection angle.

Thus, according to the present invention, it is possible to provide a thin-film lamination in which a thin film having superior crystallinity, satisfactory piezoelectric property, electrostriction property, ferroelectric property or electro-optic property can be produced in an epitaxial growth manner, and to provide an actuator device, a filter device, ferroelectric memory and an optical deflection device employing the thin-film laminations.

### BRIEF DESCRIPTION OF THE DRAWINGS

Other objects and further features of the present invention will become more apparent from the following detailed description when read in conjunction with the accompanying drawings:

FIG. 1 shows an exploded perspective view of a thin-film lamination according to a first mode of carrying out the present invention;

FIG. 2 illustrates a crystal structure of a C-rare earth structure;

FIG. 3 illustrates a crystal structure of an A-rare-earth structure;

FIG. 4 illustrates a structure of a simple perovskite lattice;

FIG. 5A shows an X-ray diffraction pattern in a thin-film lamination according to a first embodiment of a first mode of carrying out the present invention;

FIG. 5B shows an X-ray diffraction pattern according to a comparison example;

FIG. 6 shows an X-ray diffraction pattern in φ scanning for a thin-film lamination according to the first embodiment;

FIG. 7 shows a relationship between an orientation of a simple perovskite structure film and a lattice constant of a C-rare earth structure film;

FIG. 8 shows an exploded perspective view of a thin-film lamination according to a variant example of the first mode of carrying out the present invention;

FIG. 9 shows a side elevational sectional view of an actuator device according to a second mode of carrying out the present invention;

FIG. 10 shows a side elevational sectional view of an actuator device according to a first variant example of the second mode of carrying out the present invention;

FIG. 11 shows a side elevational sectional view of an actuator device according to a second variant example of the second mode of carrying out the present invention;

FIG. 12 shows a side elevational sectional view of an actuator device according to a third variant example of the second mode of carrying out the present invention;

FIG. 13A shows a side elevational sectional view of a filter device according to a third mode of carrying out the present invention;

FIG. 13B shows a plan view of the filter device shown in FIG. 13A;

FIG. 14 shows a side elevational sectional view of a ferroelectric memory according to a fourth mode of carrying out the present invention;

FIG. 15A shows a side elevational sectional view of an optical deflection device according to a fifth mode of carrying out the present invention;

FIG. 15B shows a plan view of the optical deflection device shown in FIG. 15A;

FIG. 16 shows a side elevational sectional view of an optical deflection device according to a first variant example of the fifth mode of carrying out the present invention;

FIG. 17 shows a side elevational sectional view of an optical deflection device according to a second variant example of the fifth mode of carrying out the present invention;

FIG. 18 shows a side elevational sectional view of an optical deflection device according to a third variant example of the fifth mode of carrying out the present invention; and

FIG. 19 shows a side elevational sectional view of an optical deflection device according to a fourth variant example of the fifth mode of carrying out the present invention.

### DETAILED DESCRIPTION OF THE PREFERRED EMBODIMENTS

Since a lattice constant of zirconia is 0.51 nm while a lattice constant of a typical perovskite oxide such as barium titanate, PZT or such is approximately 0.4 nm, lattice constant mismatch amounts to maximum 21.6%. In such a case of low lattice matching, crystallinity in the perovskite oxide growing may be deteriorated.

Further, according to Japanese Laid-open Patent Application No. 09-110592, a barium titanate film grows without rotating with respect to a zirconia film, and 3 lattices of zirconia film grow with respect to 4 lattices of barium titanate film. However, stress tends to be concentrated on an interface in the film which grows while such large misfit is involved, and, for example, in a case where a film to be used, for example, for an optical waveguide, is made to grow on the order of 1 μm, peeling is likely to occur.

The present invention has been devised in consideration of the above-mentioned problems, and an object of the present invention is to provide a thin-film lamination in which a thin film having superior crystallinity, satisfactory piezoelectric property, electrostriction property, ferroelectric property or electro-optic property can be produced in an epitaxial growth manner, and to provide an actuator device, a filter device, a ferroelectric memory and an optical deflection device employing the thin-film laminations.

Modes of carrying out the present invention and embodiments of the present invention are described with reference to the figures.

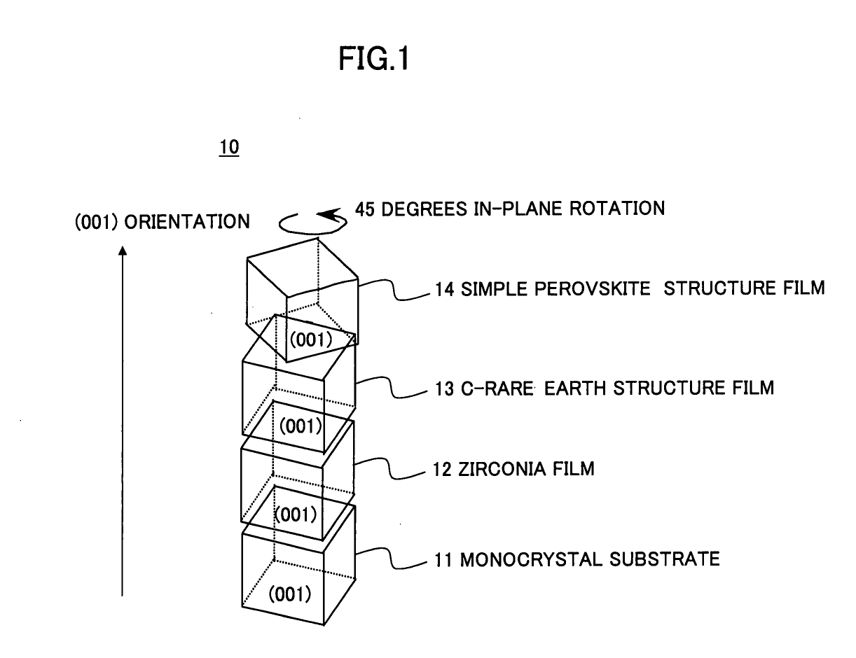

FIG. 1 shows an exploded perspective view of a thin-film lamination according to a first mode of carrying out the present invention. With reference to the figure, the thin-film lamination 10 includes a monocrystal substrate 11, and, a zirconia film 12, a C-rare earth structure film 13 and a simple perovskite structure film 14 are laminated on the monocrystal substrate 11 in the stated order in an epitaxial growth manner, where a direction of the growth is a (001) plane direction. Since the respective layers grow in an epitaxial growth manner in the (001) plane direction on the monocrystal substrate in the thin-film lamination 10, the thin-film lamination 10 has superior crystallinity. In particular, since the simple perovskite structure film 14 has the (001) plane orientation, it is possible to cause a film, made of a metal oxide having a crystal structure of simple perovskite lattices such as Pb(Zr₁₋ₓTiₓ)O₃(PZT), (Pb_{1-3y/2}La_{y}) (Zn₁₋ₓTiₓ)O₃(PLZT) or such superior in electrostriction property, ferroelectric property or electro-optic property to grow on the simple perovskite structure film in an epitaxial growth manner. The simple perovskite structure film 14 itself may have electrostriction property, ferroelectric property or elector-optic property.

The monocrystal substrate 11 is made of a silicon or gallium-arsenide (GaAs) monocrystal substrate having a principle plain of (001). As a result of the plane (001) being the principle plane, it is possible to cause plane orientations of the respective layers produced on the monocrystal substrate 11 in an epitaxial growth manner to coincide with each other, and finally, to cause plane orientation of the simple perovskite structure film 14 to lie on the (001) plane. It is also possible to apply the monocrystal substrate 11 having the principle plane of (001) but slightly inclined by an angel in a range between 0° and 4°. There is a case where a crystal interface is generated in the zirconia film 12 due to slight unevenness on the monocrystal substrate. However, by employing the monocrystal substrate 11 slightly inclined as mentioned above, it is possible to cause growth directions to coincide with each other in the zirconia film 12 and thus to suppress generation of the crystal interface.

The zirconia film 12 is made from zirconia or oxide material obtained from adding rare-earth oxide or alkaline-earth metal oxide to zirconia. When the zirconia film 12 is made of a single element of zirconia, volume change occurs during phase transformation from a cubic crystal structure in high temperature to a monoclinic crystal structure. Therefore, it is preferable that the zirconia film 12 is made from stable zirconia material obtained from adding thereto rare-earth oxide or alkaline-earth metal oxide which has reduced volume change. As preferable rare-earth oxide for the zirconia film 12, oxide containing Sc, Ce, Y, Pr, Nd, Eu, Tb, Dy, Ho, Yb, Sm, Gd, Er or La may be cited. One or a plurality of these sorts of oxide may be contained. As preferable alkaline-earth metal oxide for the zirconia film 12, oxide containing Mg, Ca, Sr or Ba may be cited. One or a plurality thereof may be contained.

In terms of lattice matching with the C-rare earth structure film 13 produced thereon, it is preferable that the zirconia film 12 has a cubic crystal structure. As such an example, calcium oxide stable zirconia containing zirconia, and CaO in a content in a range between 2 mol % and 27 mol % (preferably in particular, 13 mol % and 27 mol %) or yttria stable zirconia containing zirconia, and Y₂O₃ in a content in a range between 2 mol % and 52 mol % (preferably in particular, 4 mol % and 52 mol %) may be cited. A film thickness of the zirconia film 12 is set in a range between 10 nm and 200 nm, for example.

The C-rare earth structure film 13 is made of rare-earth oxide having a crystal structure of C-rare earth structure. A rare-earth oxide having a crystal structure of C-rare earth structure is of an A₂O₃ type, where O denotes oxygen while A denotes a rare-earth element selected from among Y, Pr, Nd, Eu, Tb, Dy, Ho, Yb, Sm and Er. Specifically, Y₂O₃, Pr₂O₃, Nd₂O₃, Eu₂O₃, Tb₂O₃, Dy₂O₃, Ho₂O₃, Yb₂O₃, Sm₂O₃ or Er₂O₃. As long as crystallinity is not remarkably deteriorated, a plurality of these rare-earth elements may be included in the C-rare earth structure film 13.

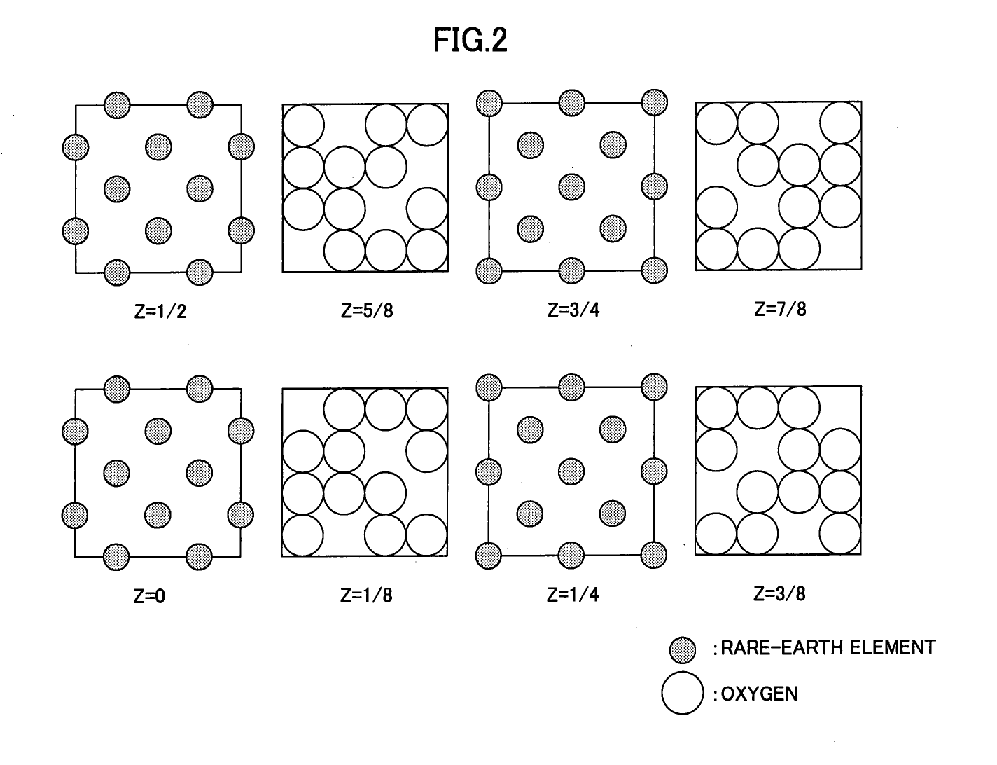

FIG. 2 illustrates a crystal structure of the C-rare earth structure. As shown in FIG. 2, the C-rare earth structure has a cubic crystal structure. A unit cell of the C-rare earth structure has a Z axis in a (001) plane direction (or a plane direction equivalent to the (001) plane), and includes 8 layers from a bottom layer (Z=0) through a top layer (Z=⅞). In the figure, each circle filled by halftone dots denotes an atom of rare-earth element, while each white circle denotes an oxygen atom. A layer configured by oxygen atoms includes holes (positions at which no oxygen atoms exist) produced. In FIG. 2, the positions of the atoms are those standardized. However, actually, the rare-earth atoms and oxygen atoms slightly shift so as to fill these holes. A lattice constant of rare-earth oxide having C-rare earth structure is in a range between 1.0 nm and 1.2 nm. Since rare-earth oxide having C-rare earth structure has a cubic crystal structure, lattice matching with the zirconia film 12 which is a base film is satisfactory, and also, lattice matching with the simple perovskite structure film 14 produced thereon is also satisfactory.

On the other hand, there is A-rare-earth oxide in the category of rare-earth oxide other than C-rare earth oxide in general.

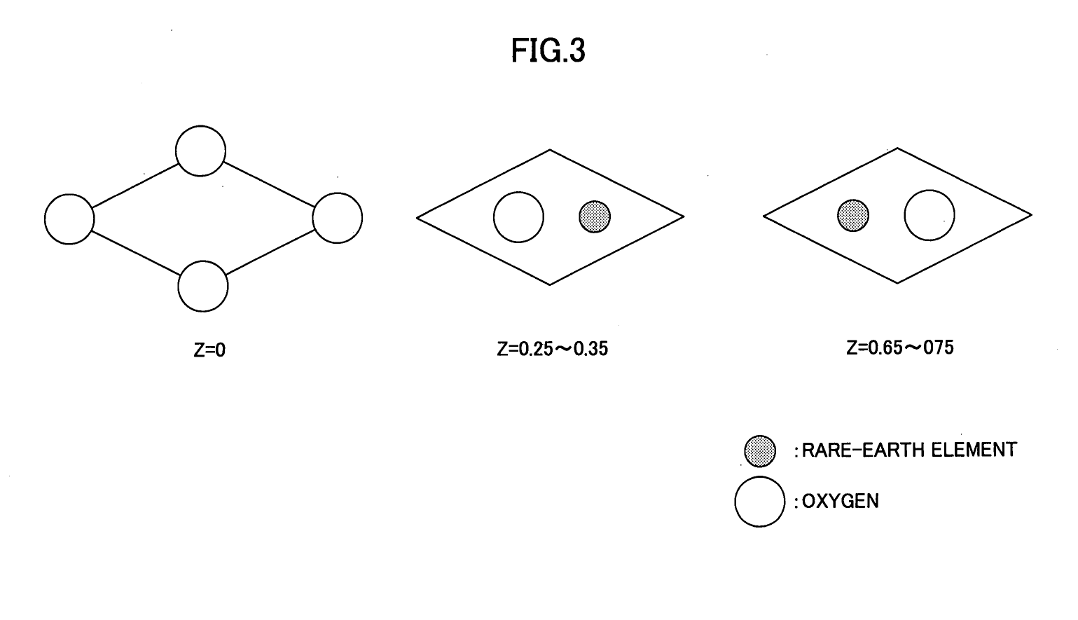

FIG. 3 illustrates A-rare-earth crystal structure. In the figure, each circle filled by halftone dots denotes a rare-earth element atom, while each white circle denotes an oxygen atom. As shown, since A-rare-earth structure has a trigonal crystal structure, lattice matching with the zirconia film and lattice matching with the simple perovskite structure film would not be satisfactory if A-rare-earth oxide were applied in the thin-film lamination instead of C-rare earth oxide. This is the reason why A-rare-earth oxide is not actually applied in the mode of carrying out the present invention. For reference, La₂O₃, Gd₂O₃ or such is an example of A-rare-earth oxide.

A film thickness of the C-rare earth film 13 is set in a range between 10 nm and 100 nm, for example.

Returning to FIG. 1, the simple perovskite structure film 14 is made of a metal oxide having a crystal structure having simple perovskite lattices. The simple perovskite structure film 14 is produced on the C-rare earth structure film 13 in a manner of being rotated by 45° about a rotation axis in the growth direction, i.e., a [001] crystal orientation in an epitaxial growth manner with the growth direction on the (001) plane.

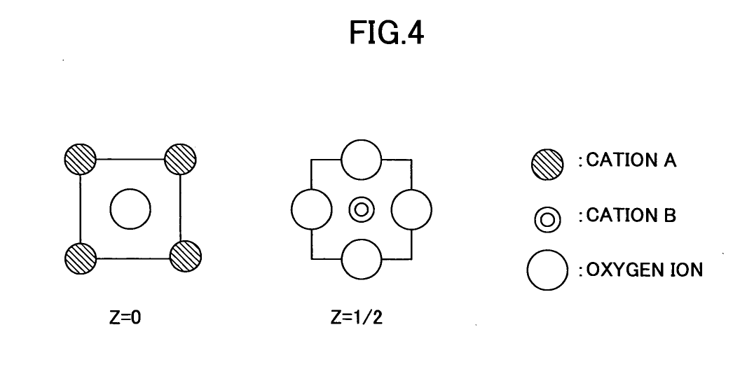

FIG. 4 illustrates a structure of a simple perovskite lattice. As shown in the figure, the simple perovskite lattice is made from cations A (denoted by hatched circles) which are metal ions, cations B (denoted by double circles) and oxygen ions (denoted by white circles). As a crystal structure having simple perovskite lattices, a perovskite structure, a bismuth layer structure, tungsten bronze structure or such may be cited. Many sorts of metal oxide having these crystal structures are ferroelectric substances, and have piezoelectric property, collecting property, electric conductive property or such.

Although metal oxide having a perovskite structure usable in the simple perovskite structure film 14 is not in particular limited, CaTiO₃ or SrTiO₃ may be cited, for example.

As preferable metal oxide having a perovskite structure usable in the perovskite structure film 14, Pb(Zr₁₋ₓTiₓ)O₃(0≦x≦1), (Pb_{1-3y/2}La_{y}) (Zr₁₋ₓTiₓ)O₃(0≦x, y≦1), Pb(B′_{1/3}B″_{2/3})ₓTi_{y}Zr_{1-x-y}O₃(0≦x, y≦1, B′ denotes bivalent metal, and B″ denotes pentavalent metal), Pb(B′_{1/2}B″_{1/2})ₓTi_{y}Zr_{1-x-y}O₃(0≦x, y≦1, B′ denotes trivalent metal, and B″ denotes pentavalent metal, or B′ denotes bivalent metal, and B″ denotes hexavalent metal), Pb(B′_{1/3}B″_{2/3})ₓTi_{y}Zr_{1-x-y}O₃(0≦x, y≦1, B′ denotes hexavalent metal, and B″ denotes trivalent metal) or (Ba₁₋ₓSrₓ)TiO₃(0≦x≦1) may be cited. These sorts of metal oxide are superior in dielectric property, electrostriction property or piezoelectric property, and, in particular, these are superior since they have large residual polarization.

Metal oxide having a bismuth layer structure usable in the perovskite structure film 14 is not limited in particular. As a preferable one, (Bi₁₋ₓRₓ)₄Ti₃O₁₂ (R denotes rare-earth element, 0≦x≦1), SrBi₂Ta₂O₉ or SrBi₄Ti₄O₁₅ may be cited. These metal oxides are superior in dielectric property, electrostriction property or piezoelectric property, and, in particular, they are superior since they have large residual polarization.

Metal oxide having a tungsten bronze structure usable in the perovskite structure film 14 is not limited in particular. As a preferable one, (Sr₁₋ₓBaₓ)Nb₂O₆(0≦x≦1), (Sr₁₋ₓBaₓ)Ta₂O₆(0≦x≦1) PbNb₂O₆(0≦x≦1), or Ba₂Na₂Nb₅O₁₅ may be cited. These metal oxides are superior in dielectric property, electrostriction property or piezoelectric property, and, in particular, they are superior since they have large residual polarization.

The simple perovskite structure film 14 may be made of a metal oxide having an electric conductivity and having a crystal structure having simple perovskite lattices. As an example of such electric conductive metal oxide, for example, SrRuO₃, SrVO₃, SrCrO₃, (La, Sr)CoO₃, CaRuO₃, CaCrO₃ or ReO₃ may be cited. These materials are referred to as ‘perovskite structure electric conductive oxide’, hereinafter.

In terms of lattice matching, as preferable combinations in material between the C-rare earth structure film 13 and the perovskite structure film 14, Dy₂O₃ and CaTiO₃ may be cited.

The above-mentioned zirconia film 12 may be produced with the use of a sputtering method, a pulse laser deposition method or such. The C-rare earth structure film 13 and the perovskite structure film 14 may be produced with the use of a sputtering method, a CVD (chemical vapor deposition) method (in particular, MOCVD (organic metal CVD)), a pulse laser deposition method, a CSD (chemical solution deposition) method, a sol-gel method or such.

A manner of epitaxial growth of the thin-film lamination 10 on the silicon substrate according to the present mode of carrying out the present invention is described with reference to a first embodiment of the present invention and a comparison example therefor.

The first embodiment of the present invention is described. According to the first embodiment, the thin-film lamination is produced as follows:

On the monocrystal silicon having a (001) plane, an yttria stabilized zirconia (YSZ) film (with a content of Y₂O₃: 8 mol %), a dysprosium oxide (Dy₂O₃) film and a calcium titanate (CaTiO₃, CTO) film were produced in the stated sequence.

Specifically, the silicon monocrystal substrate was set in a film producing chamber, the substrate temperature was set as 650° C., the pressure was set as 6.65'10⁻² Pa and an oxygen flow rate was set as 12 sccm, a KrF excimer laser beam was applied to a YSZ target, and thus, a YSZ film with a film thickness of 200 nm was produced in a pulse laser deposition method.

Then, the substrate temperature was set as 650° C., the pressure was set as 1.33 Pa, and an oxygen flow rate was set as 6 sccm, the KrF excimer laser beam was applied to a Dy₂O₃ target, and thus, a Dy₂O₃ film with a film thickness of 50 nm was produced on the YSZ film in the pulse laser deposition method.

Then, the substrate temperature was set as 650° C., the pressure was set as 1.33 Pa, and an oxygen flow rate was set as 6 sccm, the KrF excimer laser beam was applied to a CTO target, and thus, a CTO film with a film thickness of 100 nm was produced on the Dy₂O₃ film in the pulse laser deposition method. Thus, the thin-film lamination according to the first embodiment of the present invention including the silicon monocrystal substrate/YSZ film (200 nm)/Dy₂O₃ film (50 nm)/CTO film (100 nm) was produced. The parenthetic values denotes the respective film thicknesses.

A comparison example is described next. In this comparison example, a thin-film lamination was produced in a manner such that no Dy₂O₃ film was produced on an YSZ film, but a strontium titanate (SrTiO₃, simply referred to as ‘STO’ hereinafter) film was produced. Other than this manner, the comparison example was formed in the same manner as that of the first embodiment described above.

The STO film was produced on the YSZ film with a film thickness of 100 nm in a pulse laser deposition method in a condition in which a substrate temperature was set as 650° C., a pressure was set as 1.33 Pa, an oxygen flow rate was set as 6 sccm, and a KrF excimer laser beam was applied to a STO target. As a result, the thin-film lamination in the comparison example including the silicon substrate/YSZ film/STO film was produced.

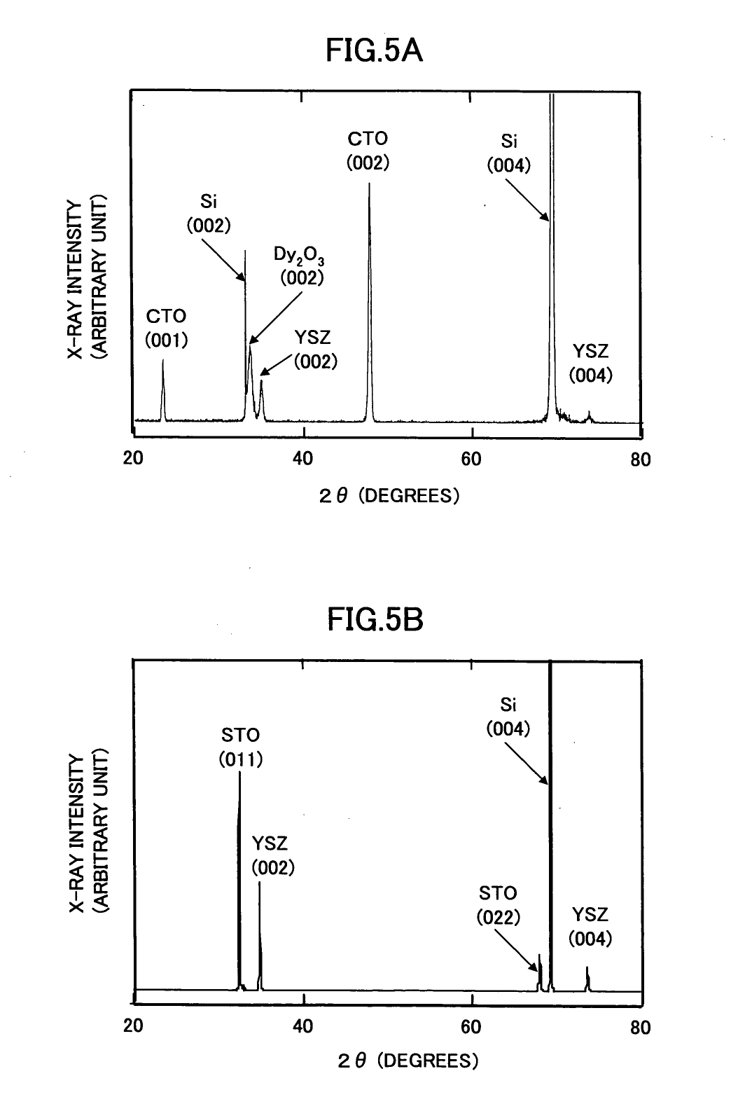

FIG. 5A shows an X-ray diffraction pattern of the thin-film lamination according to the first embodiment in the first mode of carrying out the present invention, while FIG. 5B shows an X-ray diffraction pattern of the thin-film lamination in the comparison example. The X-ray patterns were obtained with the use of an X-ray diffract meter according to an XRD method at 2θ-θ scanning.

As shown in FIGS. 5A and 5B, although (002) and (004) of the YSZ were observed from the comparison example, the STO film was oriented in (011), but (001) component was not observed. In contrast thereto, in the thin-film lamination according to the first embodiment, (002) and (004) of the YSZ, and also (002) of Dy₂O₃ and (001) and (002) of CTO were observed. On the other hand, diffraction lines of indexes of such as (0LL) or (LLL) were not observed. Therefrom, it is seen that, in the thin-film lamination according to the first embodiment, the YSZ film/Dy₂O₃ film/CTO film grew in an epitaxial manner in the (001) plane direction on the silicon substrate of the (001) plane. Therefore, it is seen that, as a result of the Dy₂O₃ film being provided on the YSZ film, it became possible to cause the CTO film on the Dy₂O₃ film to grow in the epitaxial manner in the (001) plane direction.

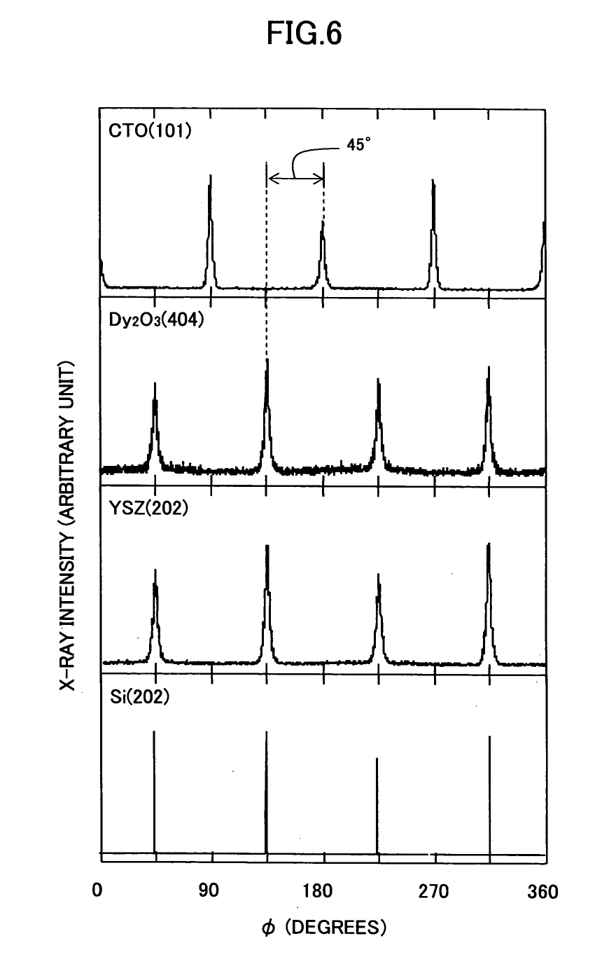

FIG. 6 shows an X-ray pattern at φ scanning for the thin-film lamination according to the first embodiment. The φ scanning was carried out along the (101) plane direction.

As shown in FIG. 6, a diffraction line corresponding to the (101) plane for each of the layers included in the thin-film lamination according to the first embodiment was observed. For the respective ones of the silicon monocrystal substrate, the YSZ film and the Dy₂O₃ film, a diffraction peak was observed at a same angle. Therefrom, it is seen that each of the YSZ film and the Dy₂O₃ film was produced in an epitaxial growth manner in a cube-on-cube manner from the relevant base layer. On the other hand, a diffraction line of the CTO was observed at an angle sifted by 40° with respect to (404) of the Dy₂O₃ film. Therefrom, it is seen that the CTO film grew in an epitaxial manner with rotation by 45° with respect to the Dy₂O₃ film with a rotation axis of the (001) plane direction.

The inventors of the present invention obtained a relationship between a component ratio of a simple perovskite structure film on the (001) plane and a lattice constant of a C-rare earth structure film from an experiment. It is noted that composition of the C-rare earth structure film was changed for the lattice constant, and the simple perovskite structure film was produced in the same method as that in the first embodiment with the use of the CTO film.

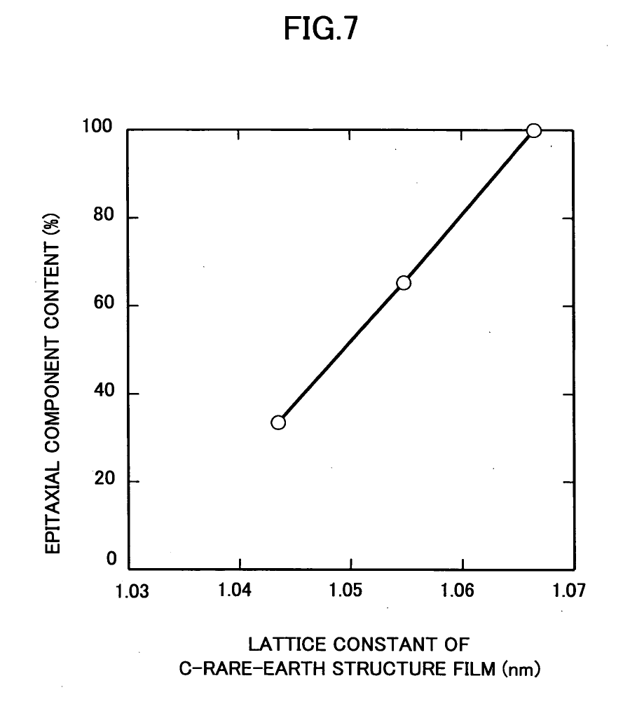

FIG. 7 shows a relationship between an epitaxial component content exhibiting (001) plane orientation in the simple perovskite structure film and a lattice constant of the C-rare earth structure film. The epitaxial component content R is defined by the following formula:
R=I(002)/{I(002)+I(011)}×100

There, I(002) and I(011) denote diffraction peak values of an index (002) and an index (011) obtained at 2θ-θ scanning in the above-mentioned XRD method, respectively. The epitaxial component content has a larger value as I(002) increases, in other words, as (001) plane orientation becomes more dominant.

As shown in FIG. 7, the epitaxial component content R monotonously increases as the lattice constant of the C-rare earth structure film increases from 1.044 nm, and, the epitaxial component content R becomes approximately 100% when the lattice constant of the C-rare earth structure film becomes around 1.066 nm. This value approximately coincides with 0.379×2√2=1.072 obtained for two unit cells of CTO and one unit cell of a C-rare earth structure film where a lattice constant of CTO (pseudo-cubic crystal) is 0.379 nm and CTO is rotated by 45° with the rotation axis of (001) plane direction. In other words, it is seen that lattice matching improves and the perovskite film becomes easy to grow epitaxially as a result of the simple perovskite structure film having a film thickness of 0.4 nm being rotated by 45°.

Accordingly, as a result of the simple perovskite film being rotated with the rotation axis of (001) plane direction on the C-rare earth structure film in an epitaxial growth manner, lattice matching improves, and thus, a superior crystal structure can be obtained.

Since the simple perovskite structure film 14 is produced with a crystal growth plane of (001) plane in the thin-film lamination according to the present mode of carrying out the invention, it is possible to cause a metal oxide of a crystal structure having simple perovskite lattices, for example, a ferroelectric film to grow epitaxially thereon, and also, it is possible to cause a crystal growth direction thereof, i.e., a lamination direction thereof, to orient in (001) direction. Accordingly, it is possible to cause the polarization direction and the lamination direction of the ferroelectric film to be coincident with one another, and, as a result, it is possible to improve piezoelectric property, electrostriction property, a residual polarization amount, or electro-optic effect of an actuator device driven as a result of an electric field being applied along a lamination direction, a filter device, a ferroelectric memory including a capacitor device, or an optical deflection device.

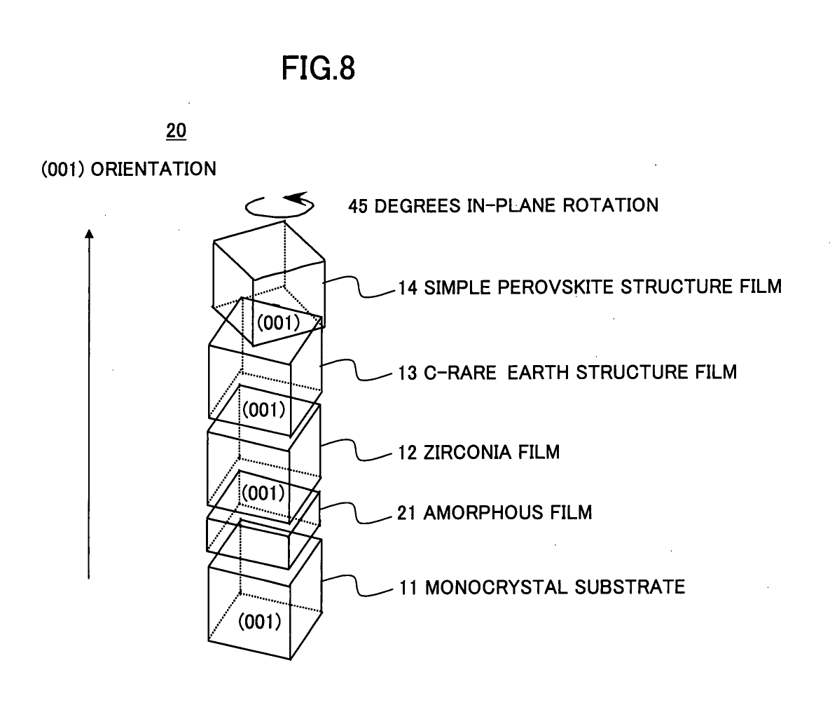

FIG. 8 shows an exploded perspective view of a thin-film lamination according to a variant example of the first mode of carrying out the present invention. In this figure, for parts/components corresponding to those already described, the same reference numerals are given and duplicated description is omitted.

As shown in FIG. 8, a thin-film lamination according to the present variant example includes a monocrystal substrate 11, and further, an amorphous layer 21, a zirconia film 12, a C-rare earth structure film 13 and a simple perovskite structure film 14 are laminated on the monocrystal substrate 11 in the stated order. Other than the point that the amorphous layer 21 is produced between the monocrystal substrate 11 and the zirconia film 12, the thin-film lamination according to the present variant example is produced the same as the above-described thin-film lamination according to the first mode of carrying out the present invention.

The amorphous layer 21 has a film thickness in a range between 10 nm and 1500 nm, produced for example as a result of a surface of the monocrystal substrate 11 being oxidized, and, is made of silicon oxide when the monocrystal substrate 11 is made of a silicon substrate. The amorphous layer 21 is produced as a result of thermal treatment being carried out after the zirconia film 12 is produced on the silicon substrate 11. Specifically, in a case where the monocrystal substrate 11 is made from silicon, while oxygen is frown at 5 L/min. under atmospheric atmosphere, thermal treatment is carried out for duration in a range between 30 minutes and 3 hours at a temperature in a range between 1000° C. and 1100° C. By this thermal treatment, oxygen diffuses to the monocrystal substrate 11 from the zirconia film 12, and the amorphous layer 21 is produced through thermal oxidization of the surface of the monocrystal substrate 11. The amorphous layer 21 separates bonding between the monocrystal substrate 11 and the zirconia film 12, and thus, further improves crystallinity thanks to auto-rearrangement in the zirconia film 12.

According to the present variant example, by further improving crystallinity in the zirconia film 12 as mentioned above, it is possible to further improve crystallinity in the C-rare earth structure film 13 and the simple perovskite structure film 14 produced thereon.

A second mode of carrying out the present invention is described next. An actuator device according to the second mode of carrying out the present invention has a configuration in which the above-described thin-film lamination according to the first mode of carrying out the present invention is used as a base member, and thereon, an oxide film or such having piezoelectric property and/or electrostriction property is produced.

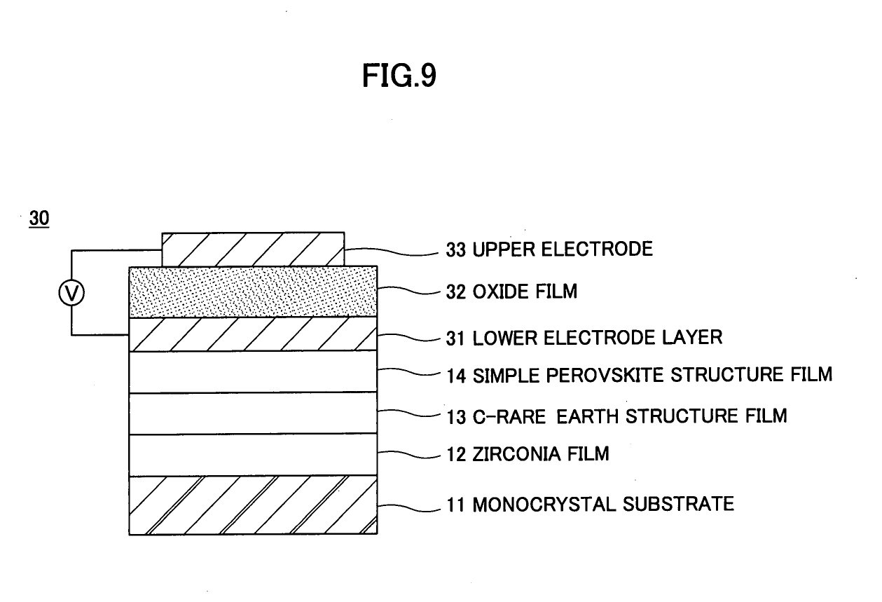

FIG. 9 shows a sectional view of an actuator device according to the second mode of carrying out the present invention. In this figure, for parts/components corresponding to those already described, the same reference numerals are given and duplicated description is omitted.

As shown in FIG. 9, the actuator device 30 according to the present mode of carrying out the present invention includes a monocrystal substrate 11, and further, thereon, a zirconia film 12, a C-rare earth structure film 13, a simple perovskite structure film 14, a lower electrode layer 31, an oxide film 32 and an upper electrode 33 are laminated in the stated order. The zirconia film 12, the C-rare earth structure film 13 and the simple perovskite structure film 14 are produced in an epitaxial growth manner in the same manner as that in the above-described first mode of carrying out the present invention. Then, further thereon, the lower electrode layer 31 and the oxide film 32 are produced in an epitaxial growth manner from the respective base layers. As a result of a voltage being applied between the lower electrode layer 31 and the upper electrode 33, thanks to piezoelectric property or electrostriction property of the oxide film 32, the actuator device expands or shrinks in a thickness direction or a plane direction of the oxide film 32. As a result, the side of the upper electrode 33 relatively moves with respect to the side of the substrate, or the device bends.

The lower electrode layer 31 is produced from, for example, electrically conductive metal oxide with a thickness of 200 nm containing a platinum group element or an alloy including a platinum group element of a crystal structure having simple perovskite lattices, and is produced in an epitaxial growth manner on the simple perovskite structure film 14. The specific element of the platinum group applicable is, for example, Ru, Rh, Pd, Os, Ir or Pt. Thereamong, especially, Ir or Pt is preferable in terms of providing superior crystal orientation. (001) plane of the lower electrode layer 31 grows on (001) plane of the simple perovskite structure film 14. Accordingly, it is possible to cause the oxide film 32 growing on the lower electrode layer 31 to orient in a (001) plane direction. Further, the electrically conductive metal oxide having the crystal structure of simple perovskite lattices is one of the various sorts of the perovskite structure eclectically conductive oxide listed in the above description of the first mode of carrying out the present invention. Furthermore, by employing the perovskite structure electrically conductive oxide as the lower electrode layer 31, it is possible to provide a configuration in which the lower electrode layer 31 also acts as the simple perovskite structure film 14. The lower electrode layer 31 is produced in, for example, a sputtering method, a deposition method or such.

Further, in terms of lattice matching, a preferable combination in material between the simple perovskite film 14 and the lower electrode layer 31 is SrRuO₃ and Pt, or CaTiO₃ and Ir, for example.

The oxide film 32 has a crystal structure having simple perovskite lattices, is made from metal oxide having piezoelectric property or electrostriction property, and is produced in an epitaxial growth manner with a growing direction of (001) plane direction on the lower electrode layer 31. As such metal oxide, metal oxide having a perovskite structure, bismuth layer structure or a tungsten bronze structure may be cited. Specifically, it is preferable to apply the metal oxide having a perovskite structure, a bismuth layer structure or a tungsten bronze structure of those listed above for the metal oxide employed in the simple perovskite structure film 14 according to the first mode of carrying out the present invention described above. Since each of these types of metal oxide has a polarization direction in a (001) plane direction, a direction of an electric field of a voltage applied between the lower electrode layer 31 and the upper electrode 33 coincides with the polarization direction. Accordingly, piezoelectric property or electrostriction property thereof is superior.

In the oxide film 32, a (011) component may be mixed to a component growing in (001) plane direction. However, since a ratio of the (001) plane direction component is higher than that in (011) plane orientation in the related art, piezoelectric property or electrostriction property is superior according to the present invention.

The oxide film 32 may be produced with the use of a sputtering method, a CVD method, a MOCVD method, a pulse laser deposition method, a CSD method, a sol-gel method, or such. Especially, the CSD method is preferable in terms of easy achievement of a large area product thereof.

The upper electrode 33 is produced on the oxide film 32 from metal, alloy or electrically conductive oxide. As a preferable material for the upper electrode 33, in terms of preventing from being oxidized, a platinum group element, Ti, Ru, electrically conductive oxide such as IrO₂, RuO₂ or such may be cited. The upper electrode 33 is not necessarily produced in an epitaxial growth manner on the oxide film 33. The upper electrode 33 may be produced by, for example, a sputtering method, a deposition method or such.

After the upper electrode 33 is produced, in order to eliminate distortion in the oxide film 32 or another damage occurring when the upper electrode 33 is produced, thermal treatment may be carried out on the actuator device 30 in an oxygen atmosphere, for example, with the use of an electric furnace, at 600° C. for 60 minutes.

A semiconductor oxide film or an electric conducive oxide film of a crystal structure having simple perovskite lattices exhibiting semiconductor property or electrically conductive property may be produced in an epitaxial growth manner between the lower electrode layer 31 and the oxide film 32, between the oxide film 32 and the upper electrode 33, or both. Specifically, for example, as the semiconductor oxide film material, SrTiO₃ in which Nb or La is doped is preferable. The dope amount is for example, 1 atomic %. Further, as the electric conductive oxide film material, SrRuO₃, CaRuO₃, LaRuO₃, LaₓSr₁₋ₓCoO₃(0≦x≦1) or LaₓSr₁₋ₓMnO₃(0≦x≦1) may be cited. As a result of polarization inversion in the oxide film 32 being repeated by application of voltage of alternate current or such between the lower electrode layer 31 and the upper electrode 33, auto-polarization in the oxide film 32 may be deteriorated due to lattice defect such as oxygen loss or such in an interface between the lower electrode layer 32 and the upper electrode 33. By providing the semiconductor or electric conductive oxide film having a crystal structure of simple perovskite lattices between the lower electrode layer 31 and the upper electrode 33 and between the upper electrode 33 and the oxide film 32 as mentioned above, deterioration of auto-polarization is suppressed while (001) orientation is maintained, and thus, it is possible to achieve a long life of superior piezoelectric property or electrostriction property of the oxide film 32.

According to the second mode of carrying out the present invention described above, in the actuator device 30, since an electric field direction of a voltage applied between the lower electrode layer 31 and the upper electrode 33 coincides with (001) plane direction of the oxide film 32 exhibiting piezoelectric property or electrostriction property, superior piezoelectric property or electrostriction property is provided, and it is possible to achieve the actuator device 30 having a large displacement amount.

A first variant example of the second mode of carrying out the present invention is described next. In an actuator device according to this variant example, the thin-film lamination according to the variant example of the first mode of carrying out the present invention described above is employed.

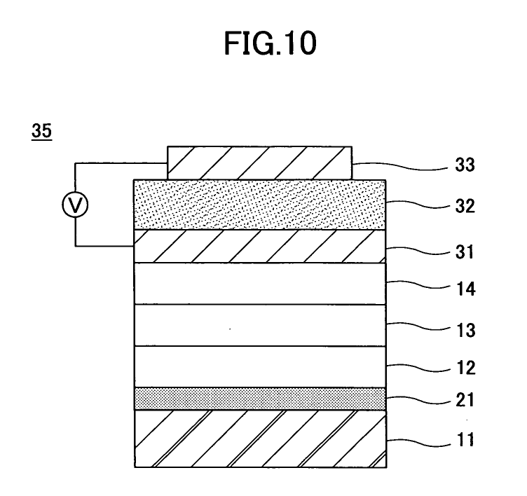

FIG. 10 shows a sectional view of an actuator device according to the first variant example of the second mode of carrying out the present invention. In this figure, for parts/components corresponding to those already described, the same reference numerals are given and duplicated description is omitted.

As shown in FIG. 10, the actuator device 35 according to the first variant example includes a monocrystal substrate 11, and further, thereon, an amorphous layer 21, a zirconia film 12, a C-rare earth structure film 13, a simple perovskite structure film 14, a lower electrode layer 31, an oxide film 32 and an upper electrode 33 are laminated in the stated order. Other than the point that the amorphous layer 21 is provided between the monocrystal substrate 11 and the zirconia film 12, the actuator 35 is the same as the actuator 30 according to the second mode of carrying out the present invention described above. Since the amorphous layer 21 is the same as that described above for the variant example of the first mode of carrying out the present invention described above, duplicated description is omitted.

According to the first variant example, by providing the amorphous layer 21, bonding between the monocrystal substrate 11 and the zirconia film 12 is separated, and as a result, thanks to auto-rearrangement in the zirconia film 12, it is possible to further improve crystallinity. Then, further by continuing from the crystallinity of the zirconia film 12, it is possible to also improve crystallinity in the oxide film 32, and as a result, it is possible to achieve the actuator device having further superior piezoelectric property or electrostriction property and having a large displacement amount.

As a second variant example of the second mode of carrying out the present invention, an actuator device in which an opening is provided from the reverse side of the monocrystal substrate is described next.

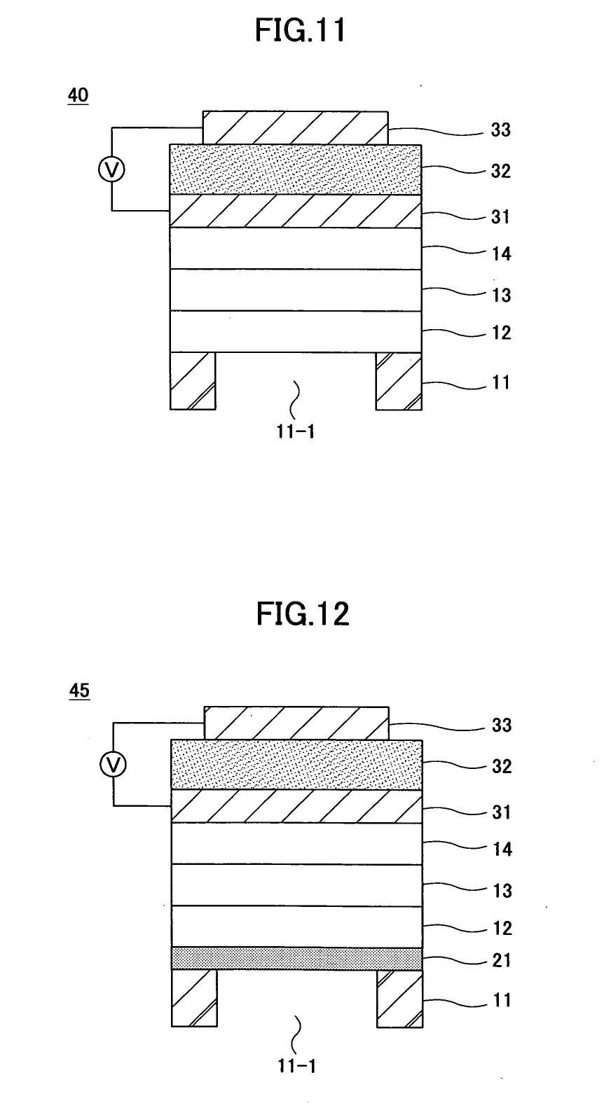

FIG. 11 shows a sectional view of an actuator device according to the second variant example of the second mode of carrying out the present invention. In this figure, for parts/components corresponding to those already described, the same reference numerals are given and duplicated description is omitted.

As shown in FIG. 11, the actuator device 40 according to the second variant example includes a monocrystal substrate 11, and further, thereon, a zirconia film 12, a C-rare earth structure film 13, a simple perovskite structure film 14, a lower electrode layer 31, an oxide film 32 and an upper electrode 33 are laminated in the stated order. Other than the point that an opening 11-1 is provided to expose the bottom surface of the zirconia film 12 from the reverse side of the monocrystal substrate 11 so as to create a diaphragm structure, the actuator device 40 is the same as the actuator device 30 according to the second mode of carrying out the present invention described above.

The opening 11-1 of the monocrystal substrate 11 is produced, for example, after production of the upper electrode 33, a resist film having an opening for an area for etching is produced on the reverse side of the monocrystal substrate 11, then, for example, the product is immersed in KOH solution having concentration of 45 mass %, and thus, etching is carried out until the zirconia film 12 is exposed. It is noted that, at this time, resist films are also produced on the surfaces of the upper electrode 33 and so forth so that they are prevented from being etched. Instead of actually exposing the zirconia film 12, merely a cavity leaving tens of μm of monocrystal substrate 11 may be provided without actually exposing the zirconia film 12.

According to the second variant example, since the diaphragm structure is created, it is possible to increase the displacement amount of the actuator device 40.

A third variant example of the second mode of carrying out the present invention is described next. In an actuator device 45 according to the third variant example as shown in FIG. 12, an amorphous layer 21 is provided between the monocrystal substrate 11 and the zirconia film 12 in the actuator device 40 according to the second variant example, the same as in the first variant example described above. In the actuator device 45 according to the third variant example, an opening 11-1 may be produced for exposing the bottom surface of the amorphous layer 21 from the reverse side of the monocrystal substrate 11. Further, not shown as a figure, a groove may be produced instead of the opening 11-1 leaving a part of the monocrystal substrate 11.

An actuator device according to a second embodiment of the present invention according to the second mode of carrying out the present invention is described next. The actuator device according to the second embodiment has the same structure as that of the second mode of carrying out the present invention shown in FIG. 9, and has a configuration of silicon monocrystal substrate/YSZ film (200 nm)/Dy₂O₃ film (50 nm)/CTO film (100 nm)/Ir film (200 nm)/PZT film (400 nm)/Pt film (150 nm). The parenthetic values show respective film thicknesses.

In the same method as that in the above-described first embodiment, a thin-film lamination of silicon monocrystal substrate/YSZ film/Dy₂O₃ film/CTO film was produced first.

Then, setting was made such as 600° C. in the substrate temperature; 1 Pa in pressure; 30 sccm in an argon flow rate; and 1 sccm in an oxygen flow rate, and then, with the use of an Ir target, an Ir film with a film thickness of 200 nm was produced on the CTO film in a sputtering method.

Then, setting was made such as 600° C. in the substrate temperature; 26.6 Pa in pressure; and 6 sccm in oxygen flow rate, and then, with the use of a PZT (52/48) target, a PZT film with a film thickness of 400 nm was produced on the Ir film in a pulse laser deposition method. There, (52/48) denotes that a mol concentration ratio between Zr and Ti is 52:48.

Then, setting was made such as the substrate temperature in a room temperature; 1 Pa in pressure; and 30 sccm in argon flow rate, and then, with the use of a Pt target, a circular Pt film with a film thickness of 150 nm was produced on the PZT film in a sputtering method with the use of a metal mask.

Then, the actuator device thus obtained was made to undergo recovery annealing processing with setting of 600° C. in the substrate temperature; atmospheric pressure; and 5 L/min. in oxygen flow rate, for 60 minutes. The recovery annealing processing was carried out mainly for the purpose of recovery from damage of the PZT film.

Thus, the actuator device according to the second embodiment was obtained. For this actuator device, by means of X-ray analysis, it was confirmed that the YSZ film/Dy₂O₃ film/CTO film/Ir film/PZT film grew epitaxially on the silicon monocrystal substrate in (001) plane direction.

An actuator device according to a third embodiment of the present invention according to the second mode of carrying out the present invention is described next. The actuator device according to the third embodiment has the same structure as that of the third variant example of the second mode of carrying out the present invention shown in FIG. 12, and has a configuration of silicon monocrystal substrate/silicon thermal oxide film (300 nm )/YSZ film (200 nm )/Dy₂O₃ film (50 nm)/CTO film (100 nm)/Pt film (200 nm )/PLZT film (200 nm )/Pt film (150 nm) with an opening in the silicon substrate. The parenthetic values show respective film thicknesses.

First, in the same method as that in the above-described first embodiment, a thin-film lamination of silicon monocrystal substrate/YSZ film was produced. Then, the silicon thermal oxide film was produced between the silicon monocrystal substrate and the YSZ film as a result of thermal treatment being carried out on the thus-obtained thin-film lamination with the use of an electric furnace with setting of: 1050° C. in the substrate temperature; atmospheric pressure; and 10 L/min. in oxygen flow rate, with supply of bubbling steam.

Then, in the same manner as that in the first embodiment described above, the Dy₂O₃ film and the CTO film were produced on the YSZ film in the stated order.

Then, setting was made such as 600° C. in the substrate temperature; 1 Pa in pressure; 30 sccm in argon flow rate; and 1 sccm in oxygen flow rate, and then, with the use of a Pt target, the Pt film with a film thickness of 200 nm was produced on the CTO film in a sputtering method.

Then, after the substrate was cooled, approximately 0.3 cm³ of commercially available PLZT thin-film production agent (PLZT113/1.5/45/55, 15 mass % in concentration) was dropped on the platinum film, which was then rotated at 3000 rpm for 20 seconds, and thus, the PLZT film was produced. PLZT113/1.5/45/55 means that molar concentration ratio between Pb, La, Zr and Ti is 113:1.5:45:55.

Then, after the PLZT film was coated, the substrate was heated on a hot plate at 350° C. for 1 minute, solvent in the PLZT film was thus volatilized, and then, the substrate was cooled to the room temperature. This process of producing the PLZT film was repeated totally four times. Then, setting was made as 650° C. in the substrate temperature, the atmospheric pressure and 5 L/min. in oxygen flow rate, the substrate was heated for ten minutes so that crystallization occurred, and thus, the PLZT film with a film thickness of 200 nm was produced.

Then, setting was made for the substrate temperature in the room temperature; 1 Pa in pressure; and 30 sccm in argon flow rate, and then, with the use of a Pt target, a circular Pt film with a film thickness of 150 nm was produced on the PLZT film in a sputtering method with the use of a metal mask. Then, a resist film as a protective film was produced on the PLZT film and the Pt film.

Then, a resist film was produced on the reverse side of the silicon monocrystal substrate, and an opening was produced in the resist film by means of patterning. Then, the substrate was immersed in saturated KOH solution at 80° C. so that anisotropic etching was carried out on the silicon monocrystal substrate and thus the bottom surface of the YSZ film was exposed, a diaphragm structure was thus produced, and then, the resist films were removed.

Then, the actuator device thus obtained was made to undergo recovery annealing processing in the same manner as that in the above-described second embodiment. Thus, the actuator device according to the third embodiment was obtained. For this actuator device, by means of X-ray analysis, it was confirmed that the YSZ film/Dy₂O₃ film/CTO film/Pt film/PLZT film grew epitaxially on the silicon monocrystal substrate in (001) plane direction.

A third mode of carrying out the present invention is described next. A filter device according to the third mode of carrying out the present invention has a configuration in which the thin-film lamination according to the first mode of carrying out the present invention described above is used as a base member, and further, an oxide film having piezoelectric property or such is provided.

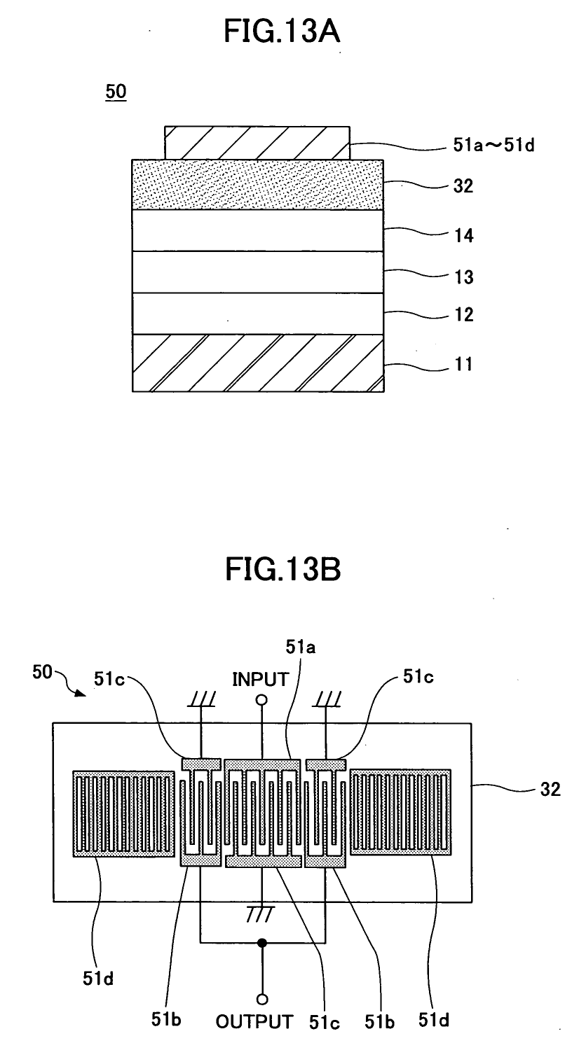

FIG. 13A shows a sectional view of the filter device according to the third mode of carrying out the present invention and FIG. 13B shows a plan view of the same. In these figures, for parts/components corresponding to those already described, the same reference numerals are given and duplicated description is omitted.

As shown in FIGS. 13A and 13B, the filter device 50 according to the present mode of carrying out the present invention includes a monocrystal substrate 11, and further, thereon, a zirconia film 12, a C-rare earth structure film 13, a simple perovskite structure film 14, an oxide film 32 and electrodes (an input-side electrode 51a, an output-side electrode 51b, a ground electrode 51c and an absorbing member 51d) are laminated in the stated order. The zirconia film 12, the C-rare earth structure film 13 and the simple perovskite structure film 14 are produced in an epitaxial growth manner in the same manner as that in the above-described first mode of carrying out the present invention. Then, further thereon, the oxide film 32 is produced in an epitaxial growth manner from the base layer with a growth direction of (001) plane direction. Further thereon, the input-side electrode 51a, the output-side electrode 51b and the ground electrode 51c are produced to have a shape like a comb, and further, the absorbing member 51d which absorbs a surface acoustic wave is produced.

The filter device 50 is a surface acoustic wave (SAW) filter, a radio frequency signal in an RF band for example is input to the input-side electrode 51a, a surface acoustic wave generated as a result of the application of the radio frequency signal thanks to piezoelectric property of the oxide film 32 is transmitted to the output-side electrode 51b, and only a frequency in a predetermined passing band is induced as an electric signal in the output-side electrode 51b.

As the oxide film 32, the material of the oxide film described above for the second mode of carrying out the present invention may also be used. Especially as preferable material for the oxide film 32 in the present mode of carrying out the present invention, PZT, for example, Pb_{1.0}Zr_{0.52}Ti_{0.48}O₃ may be cited.

The same material as that of the upper electrode 33 described above for the second mode of carrying out the present invention is used as material of the electrodes (the input-side electrode 51a, the output-side electrode 51b, the ground electrode 51c and the absorbing member 51d), and, patterning for these electrodes is archived with the use of a well-known patterning manner such as a sputtering method with the use of a metal mask or such.

According to the present mode of crying out the present invention, since crystallinity of the oxide film 32 is superior, and as a result, piezoelectric property thereof is superior, it is possible to improve transformation efficiency from an electric signal to a surface acoustic wave and also from a surface acoustic wave to an electric signal, and thus, it is possible to achieve the filter device 50 having a reduced loss. The thin-film lamination in the present mode of carrying out the present invention may be replaced by the variant example of the first mode of carrying out the present invention described above.

A fourth embodiment according to the present invention according to the above-described third mode of carrying out the present invention is described next. A filter device according to the fourth embodiment has the same configuration as that of the filter device according to the third mode of carrying out the present invention described above with reference to FIGS. 13A and 13B, and has a configuration of silicon monocrystal substrate/YSZ film (200 nm )/Dy₂O₃ film (50 nm)/CTO film (100 nm)/PLZT film (200 nm)/Pt film (150 nm). The parenthetic values indicate respective film thicknesses.

First, in the same method as that in the above-described first embodiment, a thin-film lamination of the silicon monocrystal substrate/YSZ film/Dy₂O₃ film/CTO film was produced, and then, in the same method as that of the third embodiment, the PLZT film was produced.

Then, the substrate temperature was set in the room temperature, further setting was made for 1 Pa in pressure and 30 sccm in an argon flow rate, with the use of a Pt target, comb-shaped electrodes made of a Pt film were produced on the PLZT film in a sputtering method with the use of a metal mask.

Then, the filter device thus obtained was made to undergo recovery annealing processing in the same manner as that in the above-described second embodiment. Thus, the filter device according to the fourth embodiment was obtained.

For this filter device, by means of X-ray analysis, it was confirmed that the YSZ film/Dy₂O₃ film/CTO film/PLZT film grew epitaxially on the silicon monocrystal substrate in (001) plane direction.

A fourth mode of carrying out the present invention is described next. A ferroelectric memory according to the fourth mode of carrying out the present invention is a ferroelectric memory in a MFIS (metal ferroelectric metal insulator semiconductor)—FET type structure in which, on a gate, a ferroelectric capacitor film with the use of a thin-film lamination according to the first mode of carrying out the present invention described above as a base member is produced.

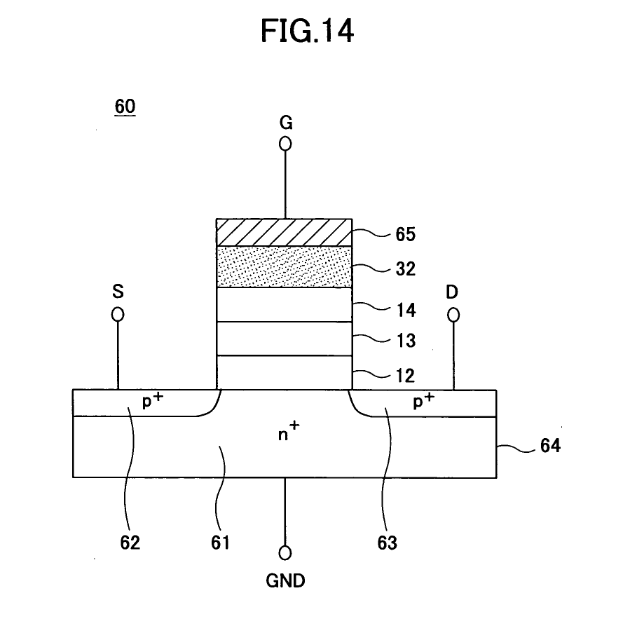

FIG. 14 shows a sectional view of the ferroelectric memory according to the fourth mode of carrying out the present invention. In this figure, for parts/components corresponding to those already described, the same reference numerals are given and duplicated description is omitted.

The ferroelectric memory 60 according to the present mode of carrying out the present invention has a configuration in which, a silicon monocrystal substrate 64 in which ‘p’-type impurity regions 62 and 63 to be used as a source S and a drain D respectively are produced in a well 61 of an ‘n’ electric conductive type connected to a ground electrode GND for example, and further, thereon, a zirconia film 12, a C-rare earth structure film 13, a simple perovskite structure film 14, an oxide film 32 having a ferroelectric property and a gate electrode 65 are laminated in the stated order. The zirconia film 12, the C-rare earth structure film 13 and the simple perovskite structure film 14 are produced in an epitaxial growth manner in the same manner as that in the above-described first mode of carrying out the present invention. Then, further thereon, the oxide film 32 is produced in an epitaxial growth manner from the base layer.

In the ferroelectric memory 60, when a voltage is applied between the gate electrode 65 and the ground electrode GND, the oxide film 32 is polarized, and the polarized electric charges influence surface electric charges in a channel produced between the impurity diffusion regions 62 and 63. Since the oxide film 32 has the ferroelectric property, this state is held, and, after that, the signal once applied to the gate electrode 65 will be able to be read out in a form of change in conductance between the source S and the drain D nondestructively.

As material of the oxide film 32, the metal oxide described above for the second mode of carrying out the present invention may be used. Since the polarization direction and the direction between the gate electrode 65 and the silicon monocrystal substrate 64 are coincident with one another, it is possible to increase a residual polarization amount. As a result, it is possible to achieve the ferroelectric memory having superior data holding performance and fatigue characteristics, and having long-term reliability.

Since the ferroelectric memory 60 can be directly produced on the silicon monocrystal substrate 64, and also, has a configuration such as to be able to act both as a transistor and also as a capacitor device, it is superior in terms of highly integrating capability. Further, since it is produced in an epitaxial growth manner and also the polarization direction and the lamination direction are coincident with one another, it is possible to suppress leakage of electric current from the oxide film 32.

Although not shown in a form of a figure, a ferroelectric memory of a MFMIS (metal ferroelectric metal insulator semiconductor)—FET type may also be provided in which a lower electrode layer is provided between the simple perovskite structure film 14 and the oxide film 32 of the gate lamination in the ferroelectric memory 60 in the present mode of carrying out the present invention. In this configuration of the MFMIS-FET type, the oxide film having ferroelectric property is provided on the floating gate. In this configuration, as the lower electrode layer, the same material as that used in the actuator device according to the second mode of carrying out the present invention may be used.

Furthermore, by providing a lower electrode between the simple perovskite structure film 14 and the oxide film 32, it is possible to use it as a capacitor device.

A fifth mode of carrying out the present invention is described next. An optical deflection device according to the fifth mode of carrying out the present invention is an optical deflection device of a waveguide type and has a configuration in which a thin-film lamination according to the first mode of carrying out the present invention described above is used as a base member.

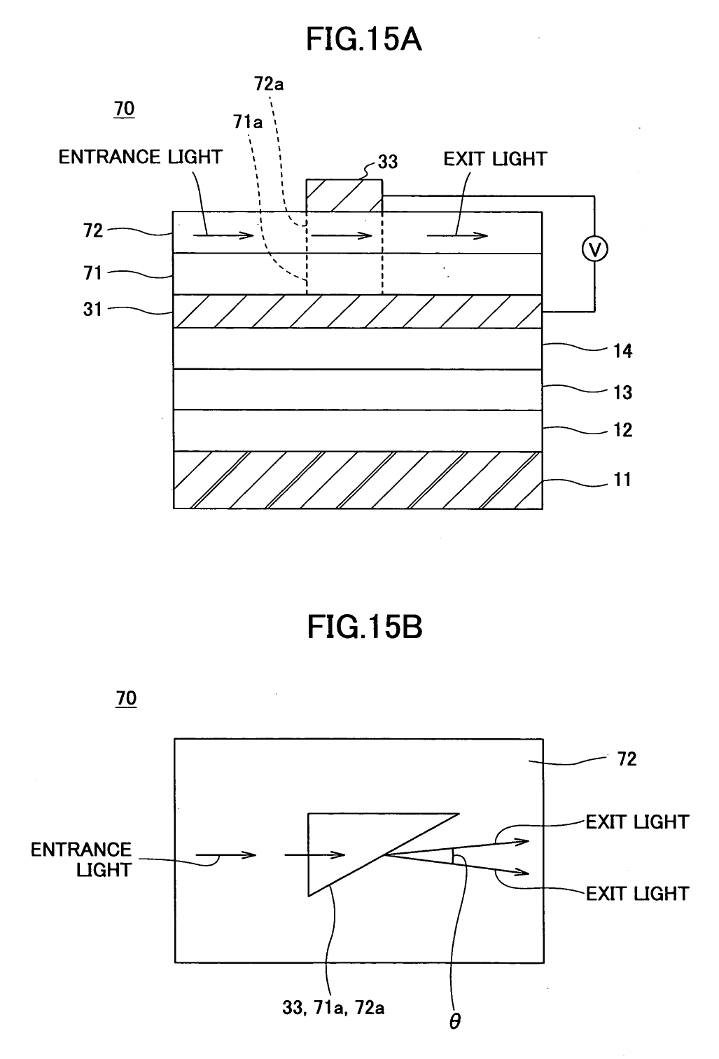

FIG. 15A shows a sectional view of the optical deflection device according to the fifth mode of carrying out the present invention and FIG. 15B shows a plan view of the same. In these figures, for parts/components corresponding to those already described, the same reference numerals are given and duplicated description is omitted.

As shown in FIGS. 15A and 15B, the optical deflection device 70 according to the present mode of carrying out the present invention includes a monocrystal substrate 11, and further, thereon, a zirconia film 12, a C-rare earth structure film 13, a simple perovskite structure film 14, a lower electrode 31, a clad layer 71, a core layer 72 and an upper electrode 33 are laminated in the stated order. The zirconia film 12, the C-rare earth structure film 13 and the simple perovskite structure film 14 are produced in an epitaxial growth manner in the same manner as that in the above-described first mode of carrying out the present invention. Then, further thereon, the lower electrode 31, the clad layer 71 and the core layer 72 are produced in an epitaxial growth manner from the respective base layers.

The optical deflection device 70 acts as a deflection device of a waveguide type, and, in response to a voltage applied between the lower electrode layer 31 and the upper electrode 33, refractive-index change regions 72a and 71a in which refractive indexes thereof change thanks to electro-optic effect are produced in the clad layer 71 and the core layer 72 below the upper electrode 33. The refractive-index change regions 71a and 72a are produced to have a triangle-pole shape and have a top surface having the same shape as that of the upper electrode 33. From light propagated in the core layer 72 and applied to the refractive-index change regions, exit light is generated from a boundary surface between the refractive-index change region 72 and the other region of the core layer 72 after being deflected with a refractive angle determined according to a refraction law from a relationship between refracted light and entrance light. In the optical deflection device 70, the refractive angel changes according to the voltage applied between the lower electrode layer 31 and the upper electrode 33, and thereby, a direction of the exit light is controllable.

The core layer 72 and the clad layer 71 have crystal structure having simple perovskite lattices, are made from metal oxide exhibiting electro-optic effect, and, for example, are made from the same metal oxide as that of the oxide film in the second mode of carrying out the present invention described above. In terms of achievement of large electro-optic effect, the core layer 72 and the clad layer 71 are preferably made from PLZT (for example, Pb_{0.865}La_{0.09}Zr_{0.65}Ti_{0.35}O₃) and PZT (for example, Pb_{1.0}Zr_{0.52}Ti_{0.48}O₃), respectively.

The core layer 72 is made from material having higher refractive index than that of the clad layer 71. For example, the core layer 72 is made of a PZT film having a refractive index of 2.45 while the clad layer 71 is made of a PLZT film having a refractive index of 2.36. By such a selection setting, light propagated in the core layer 72 is completely reflected by the surface of the clad layer 71. Since a refractive index of an air layer is on the order of 1.0, on a boundary between the core layer 72 and the air layer thereabve, light propagated in the core layer 72 is completely reflected. Accordingly, light is propagated within the core layer without spreading therefrom to any other layers.

In terms of a loss occurring due to light absorption in the clad layer 71, a refractive index of the clad layer 71 should be smaller than that of the core layer 72 by a rate of more than 0.5%. When the difference is smaller than the 0.5%, light propagated in the core layer 72 is hard to be completely reflected by the interface with the clad layer 71, and thus, a light loss increases.

In the optical deflection device 70 according to the present mode of carrying out the present invention, when a voltage applied to the upper electrode 33 with respect to the lower electrode layer 31 is swept in a range between 25V and 100V for example, a deflection angle θ of ±0.5° through 2° is obtained.

According to the present mode of carrying out the present invention, since the polarization direction of the clad layer 71 and the core layer 72 coincide with the direction between the lower electrode layer 31 and the upper electrode 33, it is possible to provide the optical deflection device having superior electro-optic effect and having a large deflection angle.

Further, since the clad layer 71 and the core layer 72 have satisfactory crystallinity in the optical deflection device 70, it has superior electro-optic effect.

Since not only the refractive index of the refractive-index change region 72a in the core layer 72 but also the refractive index of the refractive-index change region 71a in the clad layer 71 change in response to application of a voltage, it is possible to suppress increase of light loss.

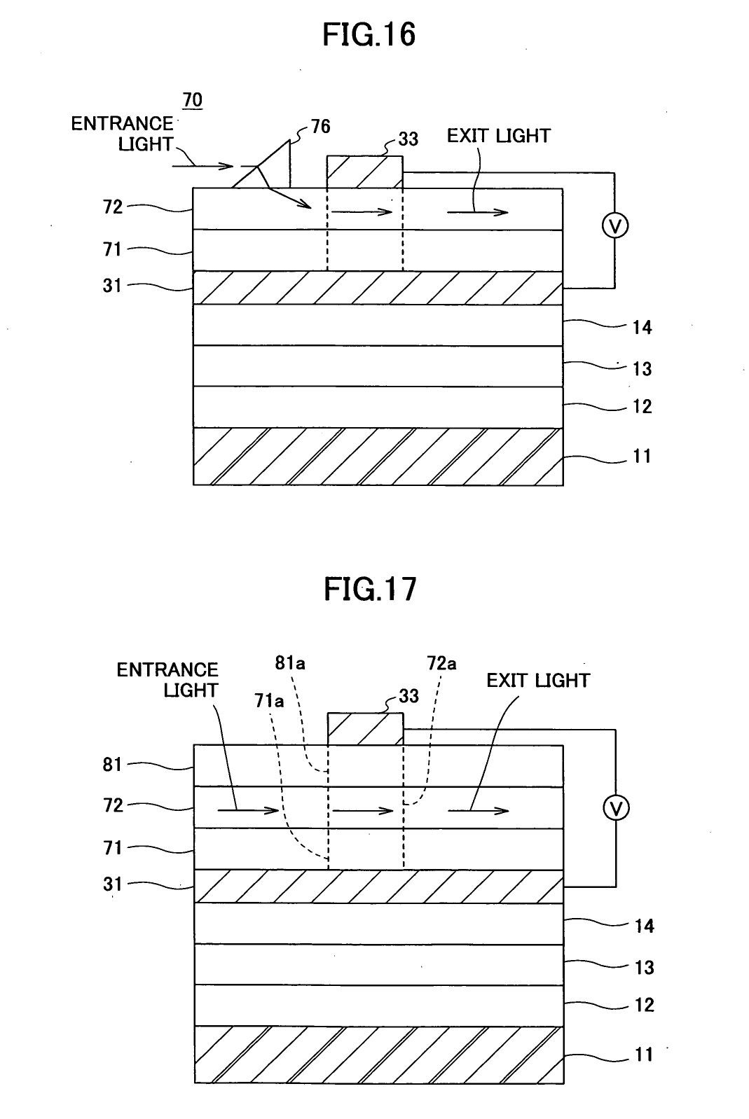

With reference to FIGS. 16 through 19, variant examples of the optical deflection device according to the present mode of carrying out the present invention are described next. In these figures, for parts/components corresponding to those already described, the same reference numerals are given and duplicated description is omitted.

FIG. 16 shows a sectional view of a first variant example of the fifth mode of carrying out the present invention. As shown in FIG. 16, the optical deflection device 75 according to the first variant example includes a monocrystal substrate 11, and further, thereon, a zirconia film 12, a C-rare earth structure film 13, a simple perovskite structure film 14, a lower electrode 31, a clad layer 71 and a core layer 72 are laminated in the stated order, and further on the core layer 72, an upper electrode 33 and a prism 76 are provided. Other than the point that the prism 76 is provided on the core layer 72, this optical deflection device has the same configuration as that of the fifth mode of carrying out the present invention described above. In this optical deflection device 75, entrance light from the outside is led to the refractive-index change region 72a in the core layer 72 by means of the prism 76, and, in the same manner as that in the optical deflection device according to the fifth mode of carrying out the present invention, the entrance light is deflected therein.

FIG. 17 shows a sectional view of a second variant example of the fifth mode of carrying out the present invention. As shown in FIG. 17, the optical deflection device 80 according to the second variant example includes a monocrystal substrate 11, and further, thereon, a zirconia film 12, a C-rare earth structure film 13, a simple perovskite structure film 14, a lower electrode 31, a clad layer 71, a core layer 72, a clad layer 81 and an upper electrode 33 are laminated in the stated order. Other than the point that the clad layer 81 is provided on the core layer 72, this optical deflection device 80 has the same configuration as that of the fifth mode of carrying out the present invention described above.

The optical deflection device 80 according to the second variant example acts as an optical deflection device of a waveguide type, and, in the same manner as that in the optical deflection device according to the fifth mode of carrying out the present invention, entrance light, propagated in the core layer 72 with repetition of complete reflection between the upper and lower clad layers 71 and 81, is deflected, according to a voltage applied between the lower electrode layer 31 and the upper electrode 33, in a boundary surface between the refractive-index change region 72a and the other region of the core layer 72.

The clad layer 81 produced on the core layer 72 is made from metal oxide material same as that of the clad layer 71 below the core layer 72, and is produced in an epitaxial growth manner with a growth direction of a (001) plane direction on the core layer 72. Accordingly, the clad layer 81 has satisfactory crystallinity and superior electro-optic effect. As a result, a refractive index changes in the refractive-index change region 81a in the clad layer 81 according to a voltage applied, and thus, a predetermined difference in refractive index from the core layer 72 can be maintained. Accordingly, in the optical deflection device 80, it is possible to suppress light loss of the clad layer 81 in the refractive-index change regions 72a and 81a.

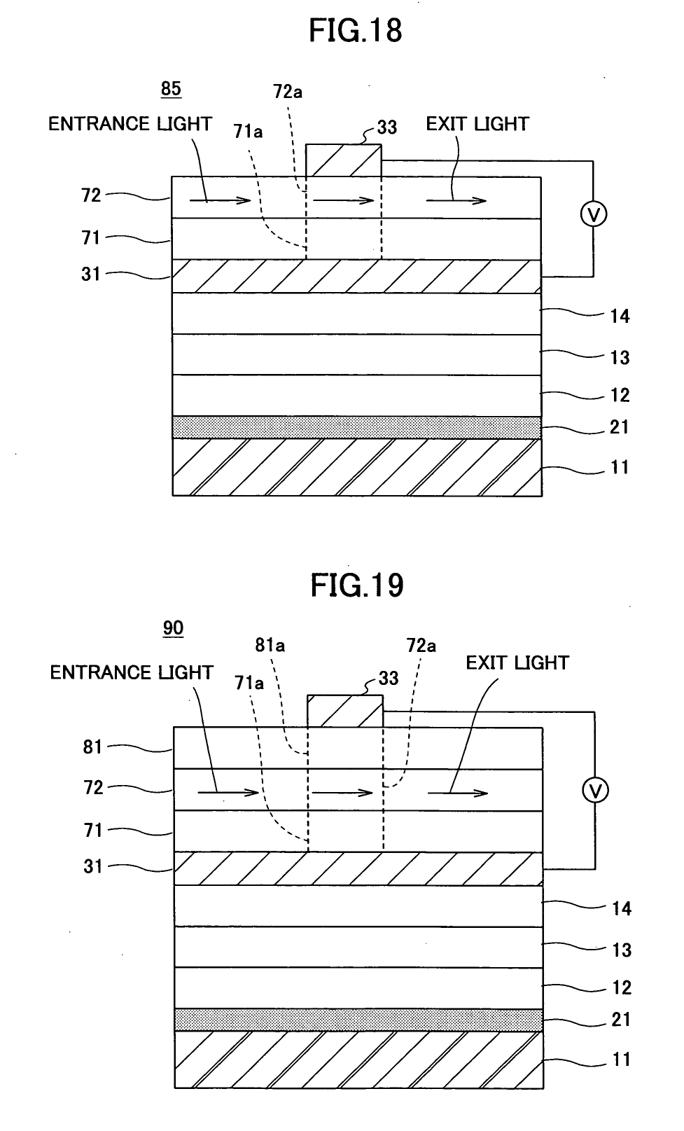

Optical deflection devices 85 and 90 according to third and an fourth variant examples of the fifth mode of carrying out the present invention shown in FIGS. 18 and 19, respectively, have configurations in each of which, an amorphous layer 21 is provided between the monocrystal substrate 11 and the zirconia film 12 in each of the optical deflection device according to the fifth mode of carrying out the present invention and the optical deflection device according to the second variant example thereof. By producing the amorphous layer 21 in the same manner as that in the thin-film lamination according to the variant example of the first mode of carrying out the present invention, crystallinity of the zirconia film 12 improves, and the crystallinity is then continued on the upper layers in sequence by means of epitaxial growth. Accordingly, crystallinity improves also in the clad layers 71 and 81 and the core layer 72, and thus, further superior electro-optic effect is obtained.

In each of the above-described first through fourth variant examples of the fifth mode of carrying out the present invention, a configuration may be created in which a single layer or film acts as both the simple perovskite structure film 14 and the lower electrode layer 81, as a result of the perovskite structure electric conductive oxide described above for the first mode of carrying out the present invention being employed for the simple perovskite structure film 14 or the lower electrode layer 31. A preferable combination in material between the simple perovskite structure film 14 and the lower electrode layer 31 is the same as that in the second mode of carrying out the present invention mentioned above.

Further, as described above, the optical deflection device according to the fifth mode of carrying out the present invention may be used as an optical waveguide. When the optical deflection device is configured as an optical waveguide, the lower electrode layer 31 and the upper electrode 33 may be omitted in each of the above-described first through fourth variant examples according to the fifth mode of carrying out the present invention.

Other than the optical deflection device, the present invention may also be applied to any of optical waveguide devices utilizing electro-optic effect such as an Brag reflector switch, a total reflection switch, a directional coupler device, a Mach-Zehnder interferential switch, a phase modulation switch, a mode transformation switch, a color filter device or such in the same manner.

A fifth embodiment according to the present invention according to the fifth mode of carrying out the present invention is described next. An optical deflection device according to the fifth embodiment has the same configuration as that of the second variant example of the fifth mode of carrying out the present invention shown in FIG. 17, and has a configuration of silicon monocrystal substrate/YSZ film (200 nm )/Dy₂O₃ film (50 nm)/CTO film (100 nm)/Pt film (200 nm )/PLZT film (2.2 μm)/PZT film (2.6 μm)/PLZT film (2.2 μm)/Pt film (150 nm). The parenthetic values show respective film thicknesses.

The same as in the third embodiment described above, a lamination of silicon monocrystal substrate/YSZ film/Dy₂O₃ film/CTO film/Pt film was produced first.

Then, after the substrate was cooled, the PLZT film acting as the lower clad layer was produced in a CSD method. Specifically, approximately 0.3 cm³ of commercially available PLZT thin-film production agent (PLZT113/9/65/35, 17 mass % in concentration) was dropped on the platinum film, which was then rotated at 3000 rpm for 20 seconds, and thus, the PLZT film was produced. PLZT113/9/65/35 means that molar concentration ratio between Pb, La, Zr and Ti is 113:9:65:35. Then, after the PLZT film was thus coated, the substrate was held for 5 minutes on a hot plate previously heated at 140° C., solvent in the PLZT film was thus volatilized, and after that, the substrate was held for 5 minutes on the hot plate previously heated to 350° C., whereby the coated film was decomposed thermally. Then, after the substrate was cooled to the room temperature, an RTA furnace was used in a condition of 650° C. in the substrate temperature and 5 L/min. in oxygen flow rate, thermal treatment was carried out for 10 minutes, and thus, the PLZT film was crystallized. A film thickness of the thus-obtained PLZT film after the crystallization was 200 nm. Then, on this PLZT film, the PLZT film was further laminated ten times in the same manner. As a result, a final film thickness of the PLZT film (lower clad layer) was 2.2 μm.

Then, the PZT film acting as the core layer was provided in a CSD method. Specifically, approximately 0.3 cm³ of commercially available PZT thin-film production agent (PZT113/52/48, 17 mass % in concentration) was dropped on the PLZT film, which was then rotated at 3000 rpm for 20 seconds, and thus, the PZT film was produced. PZT113/52/48 means that molar concentration ratio between Pb, Zr and Ti is 113:52:48. Then, after the PZT film was coated, the substrate was held for 5 minutes on a hot plate previously heated at 140° C., solvent in the PZT film was thus volatilized, and after that, the substrate was held for 5 minutes on the hot plate previously heated to 350° C., whereby the coated film was decomposed thermally. After that, in the same manner as that for the PLZT film described above, the PZT film was crystallized. A film thickness of the thus-obtained PZT film after the crystallization was 200 nm . Then, on this PZT film, the PZT film was further laminated twelve times in the same manner. As a result, a final film thickness of the PZT film (core layer) was 2.6 μm.

Then, the PLZT film acting as the upper clad layer was provided in a CSD method. Specifically, the PLZT was produced in the same manner as that for the lower clad layer described above, and as a result, a final film thickness of the PLZT film thus produced was 2.2 μm.

Then, the substrate temperature was set in the room temperature, setting is made for 1 Pa in pressure and 30 sccm in argon flow rate, with the use of a Pt target, in a sputtering method with the use of a metal mask having an opening having a triangular shape, the Pt film having a triangular shape with a film thickness of 150 nm was produced on the PLZT film.

Then, the optical deflection device thus obtained was made to undergo recovery annealing processing in the same manner as that for the second embodiment described above. Thus, the optical deflection device according to the fifth embodiment was obtained. For this optical deflection device, by means of X-ray analysis, it was confirmed that the YSZ film/Dy₂O₃ film/CTO film/Pt film/PLZT film/PZT film/PLZT film grew epitaxially on the silicon monocrystal substrate in (001) plane direction.

Further, the present invention is not limited to the above-described embodiments, and variations and modifications may be made without departing from the basic concept of the present invention claimed below.

The present application is based on Japanese priority application No. 2004-105975, filed on Mar. 31, 2004, the entire contents of which are hereby incorporated by reference.

1. A thin-film lamination comprising:
a monocrystal substrate;
an intermediate layer having zirconia as a main constituent produced in an epitaxial growth manner on the monocrystal substrate;
a C-rare earth structure film comprising oxide having a C-rare earth crystal structure produced on the intermediate layer in an epitaxial growth manner; and
a simple perovskite structure film comprising a metal oxide of a crystal structure having simple perovskite lattices produced on the C-rare earth structure film in an epitaxial growth manner.

2. The thin-film lamination as claimed in claim 1, wherein:
a growth direction of the epitaxial growth is a direction on a (001) plane; and
each of the intermediate layer and the C-rare earth structure film grows in a cube-on-cube manner on a base thereof, and the simple perovskite structure film grows on the C-rare earth structure film with rotation by substantially 45 degrees with respect to its rotation axis lying on its growth direction.

3. The thin-film lamination as claimed in claim 1, further comprising an amorphous layer produced between the monocrystal substrate and the intermediate layer as a result of a surface of the monocrystal substrate being transformed into amorphous substance.

4. The thin-film lamination as claimed in claim 3, wherein:
said monocrystal substrate comprises a silicon substrate and the amorphous layer comprises silicon oxide.

5. The thin-film lamination as claimed in claim 1, wherein:
said intermediate layer comprises the zirconia and at least one oxide selected from among a group of oxides including Sc, Ce, Y, Pr, Nd, Eu, Tb, Dy, Ho, Yb, Sm, Gd, Er and La.

6. The thin-film lamination as claimed in claim 5, wherein:
said intermediate layer comprises the zirconia and Y₂O₃; and
a content of Y₂O₃ is in a range between 2 mol % and 52 mol %.

7. The thin-film lamination as claimed in claim 1, wherein:
said intermediate layer comprises the zirconia and at least one oxide selected from among a group of oxides including Mg, Ca, Sr and Ba.

8. The thin-film lamination as claimed in claim 7, wherein:
said intermediate layer comprises the zirconia and CaO; and
a content of CaO is in a range between 2 mol % and 27 mol %.

9. The thin-film lamination as claimed in claim 5, wherein:
a crystal structure of the intermediate layer is a cubic structure.

10. The thin-film lamination as claimed in claim 7, wherein:
a crystal structure of the intermediate layer is a cubic structure.

11. The thin-film lamination as claimed in claim 1, wherein:
the C-rare earth structure film comprises oxide containing at least one element selected from among a group of Y, Pr, Nd, Eu, Tb, Dy, Ho, Yb, Sm and Er.

12. The thin-film lamination as claimed in claim 1, wherein:
the crystal structure having the simple perovskite lattices comprises any structure selected from among a group of a perovskite structure, a bismuth layer structure and a tungsten bronze structure.

13. An actuator device comprising:
a monocrystal substrate;
an intermediate layer having zirconia as a main constituent produced in an epitaxial growth manner on the monocrystal substrate.;
a C-rare earth structure film comprising oxide having a C-rare earth crystal structure produced on the intermediate layer in an epitaxial growth manner; and
a simple perovskite structure film comprising metal oxide of a crystal structure having simple perovskite lattices produced on the C-rare earth structure film in an epitaxial growth manner;
a lower electrode layer comprising a platinum group element or an alloy containing a platinum group element produced in an epitaxial growth manner on the simple perovskite structure film;
an oxide film comprising metal oxide of a crystal structure having simple perovskite lattices produced on the lower electrode film in an epitaxial growth manner; and
an upper electrode film produced on the oxide film, and wherein:
the oxide film has piezoelectric property or electrostriction property.

14. The actuator device as claimed in claim 13, further comprising an amorphous layer produced between the monocrystal substrate and the intermediate layer as a result of a surface of the monocrystal substrate being transformed into amorphous substance.

15. The actuator device as claimed in claim 13, wherein:
from a reverse side of the substrate, a groove or an opening for exposing a bottom side of the intermediate layer is produced.

16. The actuator device as claimed in claim 14, wherein:
from a reverse side of the substrate, a groove or an opening for exposing a bottom side of the intermediate layer or the amorphous layer is produced.

17. The actuator device as claimed in claim 13, wherein:
the oxide comprises any structure selected from among a group of a perovskite structure, a bismuth layer structure and a tungsten bronze structure.

18. The actuator device as claimed in claim 16, wherein:
the oxide film comprises at least one of a group including Pb(Zr₁₋ₓTiₓ)O₃(0≦x≦1), (Pb_{1-3y/2}La_{y}) (Zr₁₋ₓTiₓ)O₃(0≦x, y≦1), Pb(B′_{1/3}B″_{2/3})ₓTi_{y}Zr_{1-x-y}O₃(0≦x, y≦1, B″ denotes bivalent metal, and B″ denotes pentavalent metal), Pb(B′_{1/2}B″_{1/2})ₓTi_{y}Zr_{1-x-y}O₃(0≦x, y≦1, B′ denotes trivalent metal, and B″ denotes pentavalent metal, or B′ denotes bivalent metal, and B″ denotes hexavalent metal), Pb (B′_{1/3}B″_{2/3})ₓTi_{y}Zr_{1-x-y}O₃(0≦x, y≦1, B′ denotes hexavalent metal, and B″ denotes trivalent metal) and (Ba₁₋ₓSrₓ)TiO₃(0≦x≦1).

19. A filter device comprising:
a monocrystal substrate;
an intermediate layer having zirconia as a main constituent produced in an epitaxial growth manner on the monocrystal substrate;
a C-rare earth structure film comprising oxide having a C-rare earth crystal structure produced on the intermediate layer in an epitaxial growth manner; and
a simple perovskite structure film comprising metal oxide of a crystal structure having simple perovskite lattices produced on the C-rare earth structure film in an epitaxial growth manner; and
an input electrode and an output electrode produced on the simple perovskite structure film, wherein:
said perovskite film has piezoelectric property.

20. A filter device comprising:
a monocrystal substrate;
an intermediate layer having zirconia as a main constituent produced in an epitaxial growth manner on the monocrystal substrate;
a C-rare earth structure film comprising oxide having a C-rare earth crystal structure produced on the intermediate layer in an epitaxial growth manner; and
a simple perovskite structure film comprising metal oxide of a crystal structure having simple perovskite lattices produced on the C-rare earth structure film in an epitaxial growth manner; and
an oxide film comprising metal oxide of a crystal structure having simple perovskite lattices produced on the simple perovskite structure film in an epitaxial growth manner; and
an input electrode and an output electrode produced on the oxide film, and wherein:
said oxide film has piezoelectric property.

21. A ferroelectric memory comprising:
a monocrystal substrate in which two impurity diffusion regions connected with a source and a drain, respectively, produced thereon;
a thin-film lamination produced on the monocrystal substrate; and
a gate electrode on the thin-film lamination, wherein:
said thin-film lamination comprises:
an intermediate layer having zirconia as a main constituent produced in an epitaxial growth manner on the monocrystal substrate;
a C-rare earth structure film comprising oxide having a C-rare earth crystal structure produced on the intermediate layer in an epitaxial growth manner; and
a simple perovskite structure film comprising metal oxide of a crystal structure having simple perovskite lattices produced on the C-rare earth structure film in an epitaxial growth manner, and wherein:
the simple perovskite structure film has ferroelectric property.

22. A ferroelectric memory comprising:
a monocrystal substrate in which two impurity diffusion regions connected with a source and a drain, respectively, produced thereon;
a thin-film lamination produced on the monocrystal substrate; and
a gate electrode on the thin-film lamination, and wherein:
said thin-film lamination comprises:
an intermediate layer having zirconia as a main constituent produced in an epitaxial growth manner on the monocrystal substrate;
a C-rare earth structure film comprising oxide having a C-rare earth crystal structure produced on the intermediate layer in an epitaxial growth manner;
a simple perovskite structure film comprising metal oxide of a crystal structure having simple perovskite lattices produced on the C-rare earth structure film in an epitaxial growth manner; and
an oxide film comprising metal oxide of a crystal structure having simple perovskite lattices produced on the simple perovskite structure film in an epitaxial growth manner, and wherein:
said oxide film has ferroelectric property.

23. An optical deflection device comprising:
a monocrystal substrate;
an intermediate layer having zirconia as a main constituent produced in an epitaxial growth manner on the monocrystal substrate;
a C-rare earth structure film comprising oxide having a C-rare earth crystal structure produced on the intermediate layer in an epitaxial growth manner; and
a simple perovskite structure film comprising metal oxide of a crystal structure having simple perovskite lattices produced on the C-rare earth structure film in an epitaxial growth manner;
a lower electrode layer comprising a platinum group element or an alloy containing a platinum group element produced in an epitaxial growth manner on the simple perovskite structure film;
a first oxide film produced on the lower electrode layer in an epitaxial growth manner;
a second oxide film produced on the first oxide film in an epitaxial growth manner; and
an electrode produced on the second oxide film, and wherein:
each of the first oxide film and the second oxide film comprises metal oxide having simple perovskite lattices and also having electro-optical effect; and
the second oxide film has a refractive index higher than that of the first oxide film.

24. The optical deflection device as claimed in claim 23, further comprising a third oxide film, wherein:
said third oxide film comprises metal oxide having simple perovskite lattices and also having electro-optical effect; and
the second oxide film has a refractive index higher than that of the third oxide film.

25. The optical deflection device as claimed in claim 23, further comprising:
a prism on the second oxide film; and
a configuration whereby entrance light is led from the outside to the second oxide film through the prism.

26. The optical deflection device as claimed in claim 24, further comprising:
a prism on the second oxide film or on the third oxide film; and
a configuration whereby entrance light is led from the outside to the second oxide film through the prism.

27. The optical deflection device as claimed in claim 23, further comprising an amorphous layer produced between the monocrystal substrate and the intermediate layer as a result of a surface of the monocrystal substrate being transformed into amorphous substance.
